(19) United States
(12) Patent Application Publication
(10) Pub. No.: US 2024/0085795 A1
(43) Pub. Date: Mar. 14, 2024

(54) PATTERNING A SEMICONDUCTOR WORKPIECE

(71) Applicant: Tokyo Electron Limited, Tokyo (JP)

(72) Inventors: Jodi Grzeskowiak, Albany, NY (US); Michael Murphy, Albany, NY (US)

(21) Appl. No.: 17/943,926

(22) Filed: Sep. 13, 2022

(51) Int. Cl. G03F 7/40; G03F 7/004; G03F 7/20; H01L 21/027

(52) U.S. Cl. CPC G03F 7/40; G03F 7/0045; G03F 7/2041; H01L 21/0274

(57) ABSTRACT

In certain embodiments, a method includes depositing a photoresist layer over a semiconductor wafer to be patterned by photolithography, the photoresist layer having a first height, and exposing the photoresist layer to a pattern of actinic radiation to form exposed regions and non-exposed regions of the photoresist layer. The method further includes depositing an agent-containing layer over the photoresist layer and executing a post-exposure bake of the semiconductor wafer. The post-exposure bake modifies portions of the photoresist layer to form soluble portions of the photoresist layer for development. The soluble portions of the photoresist layer include the exposed regions and top portions of the non-exposed regions. The method further includes developing the photoresist layer to remove selectively the soluble portions, remaining portions of the non-exposed regions forming patterned structures of the semiconductor wafer and having a second height that is less than the first height.

### TECHNICAL FIELD

This disclosure relates generally to semiconductor fabrication, and, in particular embodiments, to patterning a semiconductor workpiece.

### BACKGROUND

Semiconductor devices typically are fabricated by sequentially depositing insulating or dielectric layers, conductive layers, and other layers of material over a semiconductor substrate, and patterning the layers using lithography to form circuit components and elements on the substrate. The semiconductor industry continues to increase the density of electronic components (e.g., transistors, diodes, resistors, capacitors, etc.) by continual reductions in minimum feature size, allowing more components to be integrated into a particular area.

### SUMMARY

In certain embodiments, a method includes depositing a photoresist layer over a semiconductor wafer to be patterned by photolithography, the photoresist layer having a first height, and exposing the photoresist layer to a pattern of actinic radiation to form exposed regions and non-exposed regions of the photoresist layer. The method further includes depositing an agent-containing layer over the photoresist layer and executing a post-exposure bake of the semiconductor wafer. The post-exposure bake modifies portions of the photoresist layer to form soluble portions of the photoresist layer for development. The soluble portions of the photoresist layer include the exposed regions and top portions of the non-exposed regions. The method further includes developing the photoresist layer to remove selectively the soluble portions, remaining portions of the non-exposed regions forming patterned structures of the semiconductor wafer and having a second height that is less than the first height.

In certain embodiments, a method includes depositing a photoresist layer on a semiconductor wafer to be patterned by photolithography, the photoresist layer having a first height. The method further includes depositing an agent-containing layer over the photoresist layer and executing a pre-exposure bake of the semiconductor wafer. The pre-exposure bake causes a first solubility-changing agent to diffuse from the agent-containing layer to a first portion of the photoresist layer, the first portion of the photoresist layer being disposed between the agent-containing layer and a second portion of the photoresist layer. The method further includes selectively removing the agent-containing layer and exposing, through the first portion of the photoresist layer, the second portion of the photoresist layer to a pattern of actinic radiation to form exposed regions and non-exposed regions in the second portion of the photoresist layer. The method further includes executing a post-exposure bake of the semiconductor wafer, the post exposure bake modifying the exposed regions of the second portion of the photoresist layer to be soluble for development, and developing the photoresist layer to remove selectively the first portion of the photoresist layer and the exposed portions of the second portion of the photoresist layer, as modified by the post-exposure bake. Remaining portions of the non-exposed regions of the photoresist layer form patterned structures of the semiconductor wafer and have a second height that is less than the first height of the photoresist layer.

In certain embodiments, a method includes forming first patterned structures on a semiconductor wafer, the first patterned structures defining first recesses and having a first height. Forming the first patterned structures includes depositing a photoresist layer on a semiconductor wafer to be patterned by photolithography, the photoresist layer having a second height that is greater than the first height; depositing a trimming layer over the photoresist layer; reducing, prior to developing the photoresist layer, the second height of the photoresist layer to the first height using a first solubility-changing agent diffused from the trimming layer into the photoresist layer; exposing the photoresist layer to a pattern of actinic radiation; and developing the photoresist layer, remaining portions of the photoresist layer forming microfabricated structures defining recesses. The method further includes depositing a first overcoat film on the semiconductor wafer, the first overcoat film filling the first recesses and covering the first patterned structures; diffusing a second solubility-changing agent of the first overcoat film into perimeter portions of the first patterned structures; and selectively removing the first overcoat film. The method further includes depositing a second overcoat film on the semiconductor wafer, the second overcoat film filling the first recesses and covering the first patterned structures, and executing a development process that removes a first portion of the second overcoat film to reveal the perimeter portions of the first patterned structures and removes the perimeter portions of the first patterned structures to define second patterned structures. The second patterned structures include remaining portions of the first patterned structures and second portions of the second overcoat film interspersed between the remaining portions of the first patterned structures, the second patterned structures defining second recesses.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1G illustrate cross-sectional views of an example semiconductor workpiece during an example patterning process, according to certain embodiments;

FIGS. 2A-2E illustrate cross-sectional views of an example semiconductor workpiece during an example patterning process, according to certain embodiments;

FIGS. 3A-3G illustrate cross-sectional views of an example semiconductor workpiece during an example patterning process, according to certain embodiments;

FIG. 4 illustrates an example method for patterning a semiconductor workpiece, according to certain embodiments;

FIG. 5 illustrates an example method for patterning a semiconductor workpiece, according to certain embodiments;

FIG. 6 illustrates an example method for patterning a semiconductor workpiece, according to certain embodiments;

FIG. 7 illustrates a block diagram of an example lithography system, according to certain embodiments;

FIG. 8 illustrates a block diagram of an example lithography system, according to certain embodiments; and

FIG. 9 illustrates an example liquid-based spin-on deposition system, according to certain embodiments.

### DETAILED DESCRIPTION OF ILLUSTRATIVE EMBODIMENTS

Throughout the deposition, patterning, and removal processes associated with forming a semiconductor device, certain fabricated structures may include recesses that have a high aspect ratio. The aspect ratio of a feature (e.g., a trench) generally refers to the ratio of two-dimensions of the feature (e.g., height (or depth/thickness) vs. width). A high aspect ratio may describe a structure in which one dimension is significantly larger than the other dimension. As a particular example, features having a height that is significantly greater than a width of the feature are frequently formed in layers of a semiconductor device. In general, the higher the aspect ratio, the greater the risk that certain patterning defects, such as pattern wiggling and pattern collapse, may occur. Pattern wiggling may refer to a scenario in which patterned lines are not linear. Pattern collapse could include any number of symptoms but ultimately results in a failure of a pattern to be consistent with the target pattern.

As an example, a circuit element/feature may be a contact, and a recess formed in one or more layers during one or more etch processes may have a high aspect ratio in which the depth of the recess is significantly greater than a width of the recess. As a particular example, an organic layer (e.g., a spin-on carbon anti-reflective coating) may be used as an etch mask in forming a recess (e.g., a contact hole). Prior to the organic layer being used as an etch mask, an overlying photoresist layer may be used as an etch mask to pattern recesses in the organic layer, and the depth of these recesses may be greater than the width of these recesses, possibly significantly. A straight critical dimension profile in a high aspect ratio feature (e.g., (e.g., contact holes, metal lines, fins, gate lines, vias, or other elements) may be important in certain devices. For example, preserving a straight critical dimension in a high aspect ratio etch may be difficult especially at or below 10 nanometer technology nodes.

Another challenge with high aspect ratios for narrow recesses in a patterned layer is the verticality of the recess with respect to an underlying layer. If sidewalls of the recess are tilted, accurately transferring a target pattern to an underlying layer (e.g., using an anisotropic etch process such as reactive ion etching (RIE)) may be more difficult due to shadowing effects preventing the reactive etch species from penetrating the full depth of the recess.

One example area in which high aspect ratio processing may be encountered is during photolithography. Forming features in semiconductor devices typically involves a photolithography process that generally includes forming, through photolithography, a pattern in a photoresist layer, and then transferring that pattern to one or more underlying layers for further fabrication steps. In a lithography process, a patterned mask formed from a photoresist layer is used to form features. However, defects in the patterned mask may propagate to a feature being formed. Problems associated with such defects in the features being formed may be amplified at smaller technology nodes.

The wavelength of radiation, which may be determined according to the photolithography technique being used, may affect the minimum feature size achievable during semiconductor fabrication. Some newer technologies, such as extreme ultraviolet (EUV) lithography, are able to directly achieve relatively small feature sizes, approaching a 13 nm half pitch using EUV 13.5 nanometer wavelength at 0.33 numerical aperture (NA). However, these newer technologies may suffer certain drawbacks, including expense.

Some older lithography technologies, such as 193 nanometer immersion technology, i-line technology, and others, remain commonly used and may be used in combination with other processes to achieve smaller features sizes than may be achieved directly using the older lithography technology. For example, 193 nanometer immersion lithography may be used in combination with an anti-spacer patterning process to achieve sub-resolution feature sizes of less than 15 nanometers, and potentially down to 10 nanometers or less. Anti-spacers may be formed through lateral diffusion of a solubility-changing agent (e.g., acid) in organic films, such as a photoresist and polymer overcoat.

In some cases, the primary photoresist pattern for the anti-spacer is generated using older lithographic technologies, such as 193 nanometer immersion and/or i-line technologies, to reduce high-volume manufacturing (HVM) cost. At these lithographic technologies, the photoresist film thicknesses may be in the range of 100 nanometers to 1 micrometer. This photoresist thickness may present challenges for anti-spacer patterning processes. For example, for anti-spacer trenches of 10 nanometers, the aspect ratio of the trench may be 10:1 for 193 nanometer immersion lithography, and potentially up to 100:1 for i-line lithography, any of which might experience a loss of pattern fidelity. As a particular example, applying sub-10 nanometer anti-spacer technology to older lithographic technologies (e.g., 193 nanometer immersion) with relatively thick photoresists (e.g., >50 nanometers) may result in a feature aspect ratio concern that impacts pattern fidelity and the ability to properly transfer the pattern into an underlying hardmask.

Certain embodiments of this disclosure provide techniques to reduce an aspect ratio that may be encountered during semiconductor fabrication, such as during a patterning process. For example, certain embodiments provide techniques for reducing a thickness of a photoresist layer prior to a development process for developing the exposed photoresist. In certain embodiments, the photoresist thickness is reduced after an exposure lithographic step for processing the photoresist. In certain embodiments, the photoresist thickness is reduced prior to the exposure lithographic step. In certain embodiments, the photoresist thickness is reduced with little to no impact on an integrity of a lithography process for patterning the photoresist. For example, the thickness of the photoresist may be reduced with little to no impact on a critical dimension (e.g., width) of a patterned structure (e.g., line) for of the photoresist.

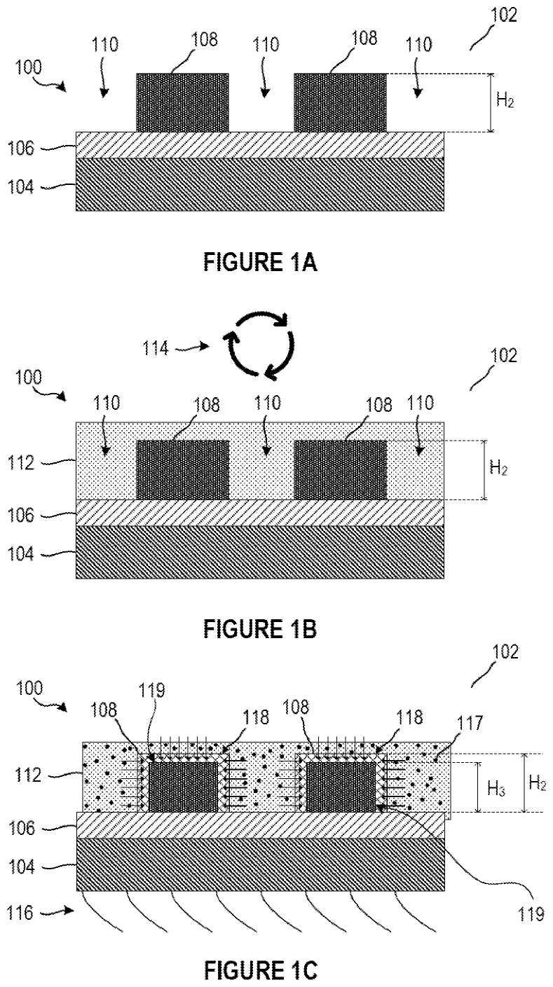

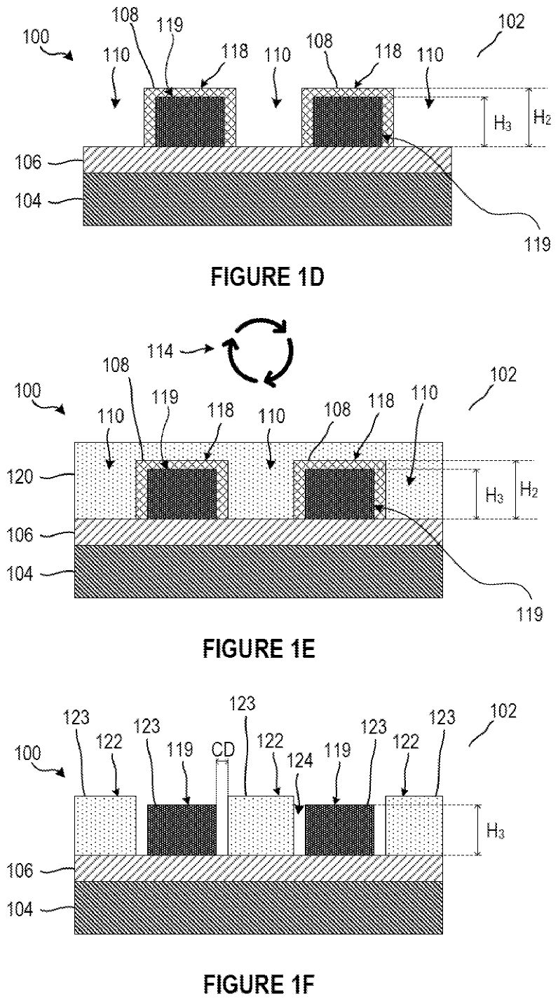

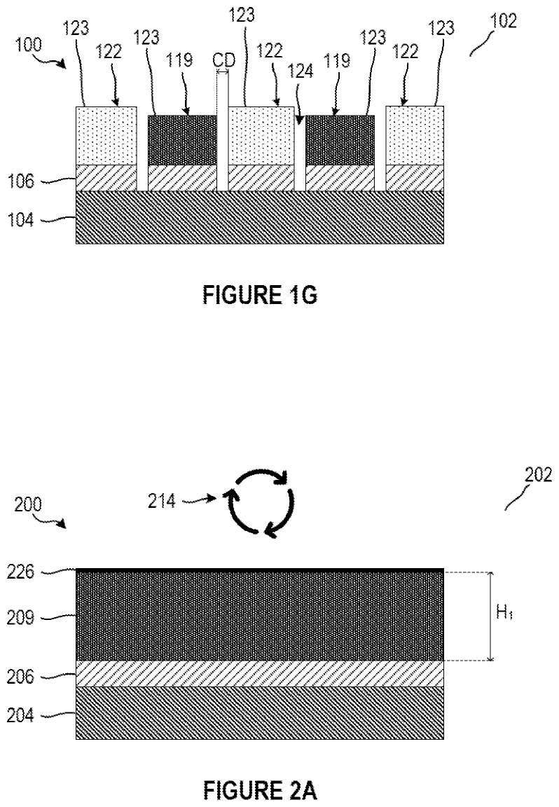

FIGS. 1A-1G illustrate cross-sectional views of an example semiconductor workpiece 100 during an example patterning process 102, according to certain embodiments. In certain embodiments, some or all of patterning process 102 may be referred to as an anti-spacer patterning process, or simply as an anti-spacer process. In certain embodiments, patterning process 102 may be used to achieve sub-resolution features in an underlying layer of a semiconductor wafer. Sub-resolution features may refer to features that are smaller than can be achieved directly according to a wavelength of the lithography technology being used (e.g., without the use of some additional patterning process, such as an anti-spacer process).

Semiconductor workpiece 100 generically refers to any suitable semiconductor element being processed in accordance with embodiments of this disclosure. Semiconductor workpiece 100, or portions thereof, also may be referred to as a semiconductor wafer, such as a silicon wafer. Semiconductor workpiece 100 includes a substrate 104, an intermediate layer 106 positioned on substrate 104, and patterned structures 108 positioned on intermediate layer 106.

Substrate 104 may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate 104 is not limited to any particular base structure, underlying layer or overlying layer, patterned or un-patterned, but rather, may include any such layer or base structure, and any combination of layers and/or base structures. Substrate 104 may be a bulk substrate such as a bulk silicon wafer, a silicon-on-insulator (SOI) wafer, or various other semiconductor substrates.

Intermediate layer 106 and patterned structures 108 may be a photolithography stack. Intermediate layer 106 also may be referred to as an underlying layer, particularly when described relative to patterned structures 108 or the layer from which patterned structures 108 are formed. This disclosure contemplates substrate 104 and intermediate layer 106 having any suitable thicknesses.

Intermediate layer 106 represents any suitable combination of one or more layers, one or more of which are to be patterned using patterned structures 108. For example, intermediate layer 106 may include a hard mask layer, an amorphous carbon layer, a silicon carbide layer, a bottom anti-reflective coating, and/or any other layer, one or more of which may be useful for a patterning process. Additionally or alternatively, intermediate layer 106 may include a stack of films. For example, intermediate layer 106 may include films of dielectric and/or conductive materials, such as oxide, silicon oxide, silicon nitride, silicon oxynitride, silicon carbide, titanium nitride, tantalum nitride, their alloys, and combinations thereof. For example, intermediate layer 106 can be a dielectric layer or alternating dielectric layers.

Semiconductor workpiece 100 may be formed in any suitable manner, including using any suitable combination of wet and/or dry deposition and etch techniques. For example, semiconductor workpiece 100 may be deposited using any technique appropriate for the material to be deposited and the semiconductor feature being formed. Suitable deposition processes may include a spin-on coating process, a chemical vapor deposition (CVD) process, an atomic layer deposition (ALD) process, plasma deposition processes (e.g., a plasma-enhanced CVD (PECVD) process), and/or other layer deposition processes or combinations of processes.

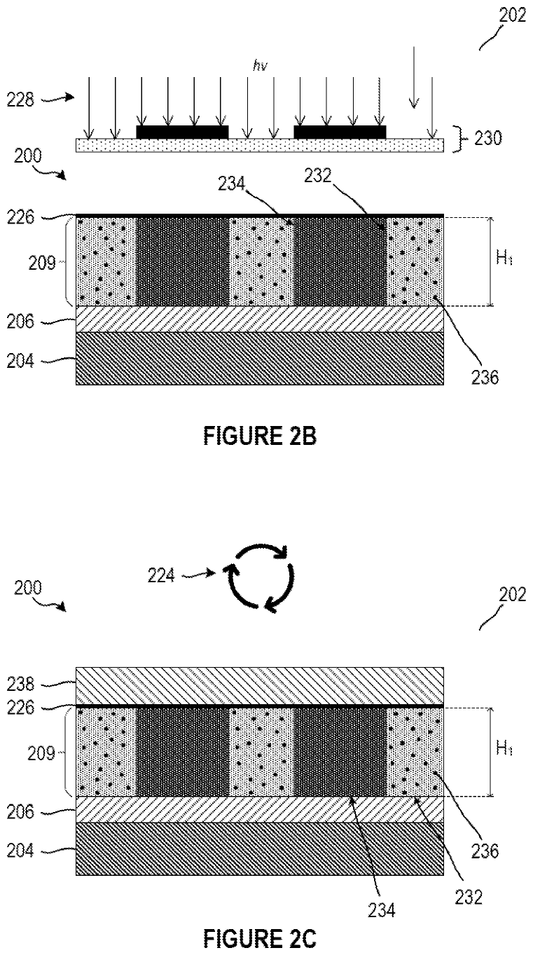

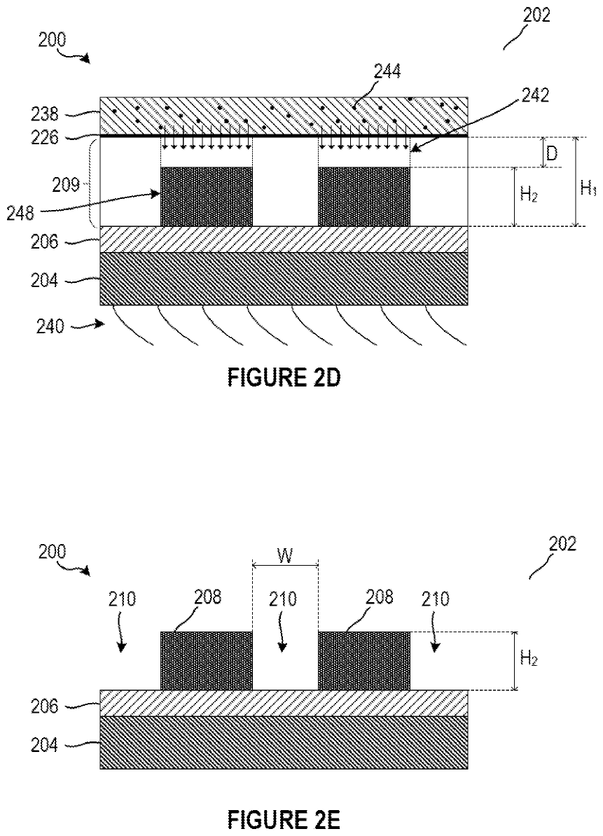

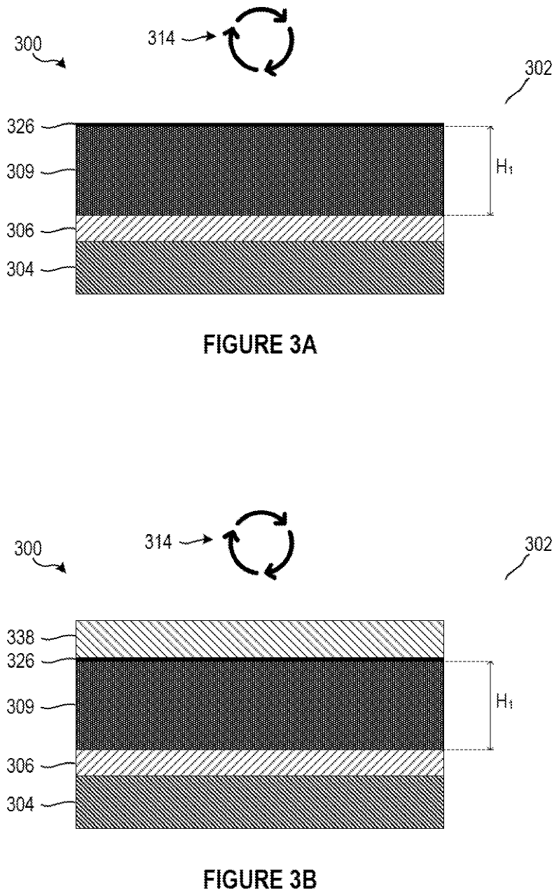

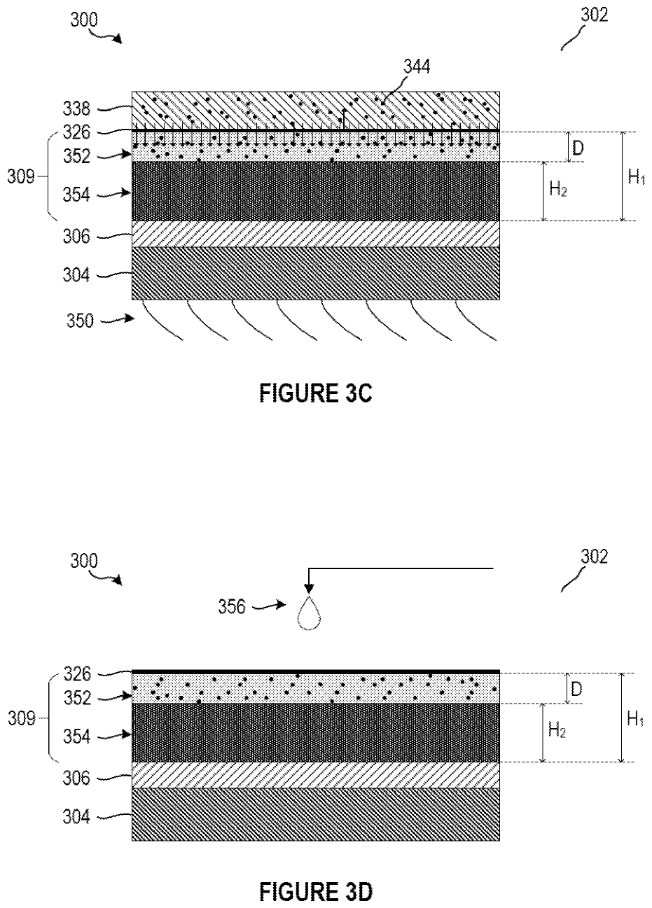

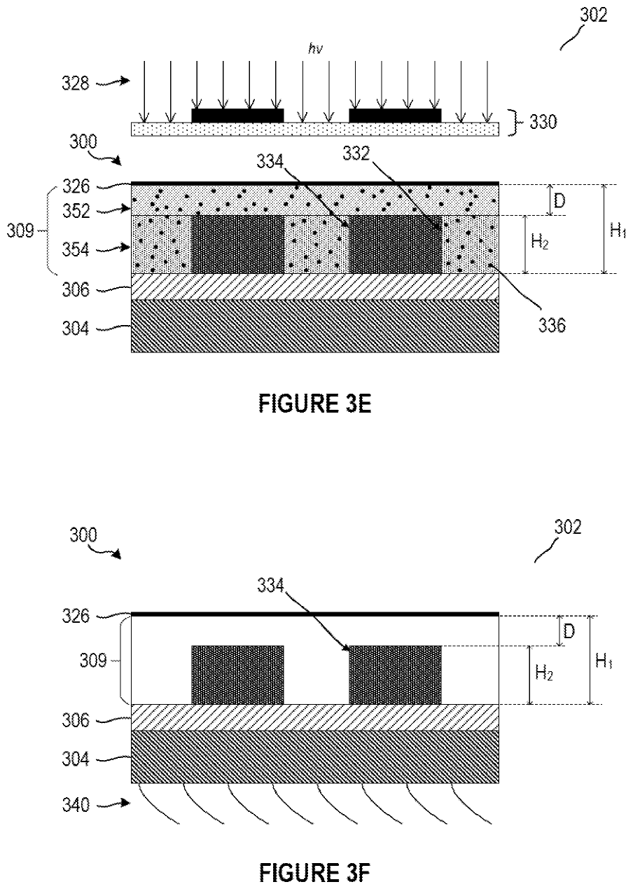

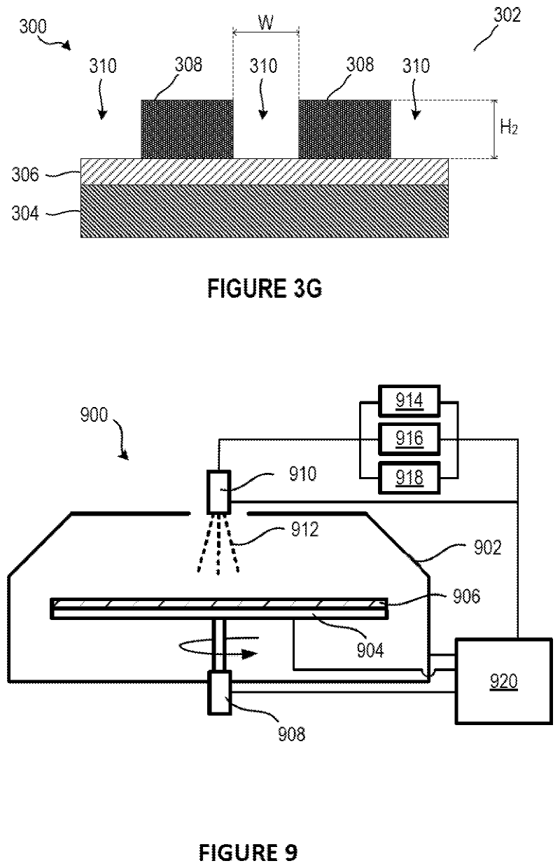

Patterned structures 108 may be formed of any suitable material and may be lines or other suitable types of semiconductor structures. In certain embodiments, patterned structures 108 are formed of a photoresist material. Additional details related to possible content of patterned structures 108 and techniques for forming patterned structures 108 are described below with reference to FIGS. 2A-2E and 3A-3G. Furthermore, patterned structures 108 may be formed using any suitable type of lithographic technology.

Patterned structures 108 may be formed from a layer of photoresist material. To form patterned structures 108, a photoresist layer may be processed in two primary stages to create a pattern for further processing underlying layers (e.g., intermediate layer 106): an exposure stage and a development stage. During the exposure stage, the photoresist material reacts to ultraviolet (UV) or other light to form a pattern on the photoresist material according to a pattern mask. Depending on the type of photoresist material used, portions of the photoresist that are exposed to UV light may become more or less soluble in a developer solution, such that those exposed regions may become more difficult or less difficult, respectively, to remove when processed using the developer solution. For example, due to exposure to the UV light, portions of the photoresist that are exposed to the UV light may have different material properties than non-exposed regions of the photoresist. The different material properties may include volatility, reactivity, and/or solubility, for example. During the development stage, the photoresist material is exposed to a developer solution to remove portions of the photoresist layer.

Patterned structures 108 may have any suitable thickness, referred to throughout this disclosure as height (labeled as H₂). In certain embodiments, photoresist layer 110 has a thickness of 5 nm to 100 nm, for example 10 nm to 30 nm. It should be understood that these thickness values are provided as examples only, and that photoresist layer 109 may have any suitable thickness. For reasons explained in greater detail below, it may be desirable to reduce the height of patterned structures 108 relative to conventional techniques.

Recesses 110 may be defined by patterned structures 108. It should be understood that although two patterned structures 108 are shown, additional patterned structures 108 may be formed laterally from the illustrated patterned structures 108. Recesses 110 may have any suitable lateral dimension. Although this disclosure primarily describes “recesses,” other suitable features might be formed in or on a semiconductor substrate, including (whether or not considered “recesses”) lines, holes, trenches, vias, and/or other suitable structures, using embodiments of this disclosure.

As described in greater detail below following FIG. 1G, the patterning process used to form patterned structures 108 shown in FIG. 1A is implemented according to the concepts described in this disclosure, which results in a height (H₂) of patterned structures 108 being reduced prior to performing subsequent steps of patterning process 102.

To create features having smaller critical dimension that those of patterned structures 108, additional processing may be performed. In this particular example, an anti-spacer patterning process may be performed on the semiconductor workpiece 100 of FIG. 1A.

As shown in FIG. 1B, an overcoat film 112 may be deposited on semiconductor workpiece 100. Overcoat film 112 may fill recesses 110 and cover patterned structures 108. Overcoat film 112 may be a multicomponent material that, as deposited, includes a first component and a second component. The first component could be, for example, a polymer. The second component could be, for example, a solubility-changing agent, such as an acid (e.g., a free acid). The second component could be, as another example, an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate acid in response to heat or a photoacid generator (PAG) that is configured to generate acid in response to actinic radiation.

Overcoat film 112 may be deposited on semiconductor workpiece 100 in any suitable manner. For example, overcoat film 112 may be deposited by spin-coating, spray-coating, dip-coating, or roll-coating. As a particular example, overcoat film 112 may be deposited on semiconductor workpiece 100 using a spin-on deposition technique 114, which also may be referred to as spin-coating.

With spin-on deposition, a particular material (e.g., the material of overcoat film 112) is deposited on a substrate (e.g., on intermediate layer 106 formed on substrate 104). The substrate is then rotated (if not already rotating, possibly at a relatively low velocity) at a relatively high velocity so that centrifugal force causes deposited material to move toward edges of the substrate, thereby coating the substrate. Excess material is typically spun off the substrate. In certain embodiments, spin-on deposition technique 114 includes dispensing liquid chemicals onto semiconductor workpiece 100 (e.g., on a top surface of intermediate layer 106 and over exposed surfaces of patterned structures 108) using a coating module with a liquid delivery system that may dispense one or more types of liquid chemicals. The dispense volume can be between 0.2 ml to 10 ml, for example 0.5 ml to 2 ml. The substrate (e.g., workpiece 100) may be secured to a rotating chuck that supports the substrate. The rotating speed during liquid dispense can be between 50 rpm to 3000 rpm, for example 1000 rpm to 2000 rpm. The system may also include an anneal module that may bake or apply light radiation to the substrate after the chemicals have been dispensed. It should be understood that this example spin-on deposition technique 114 and associated values are provided as examples only.

Additionally or alternatively, overcoat film 112 may be deposited using a chemical vapor deposition (CVD), plasma-enhanced CVD (PECVD), atomic layer deposition (ALD), or other suitable process.

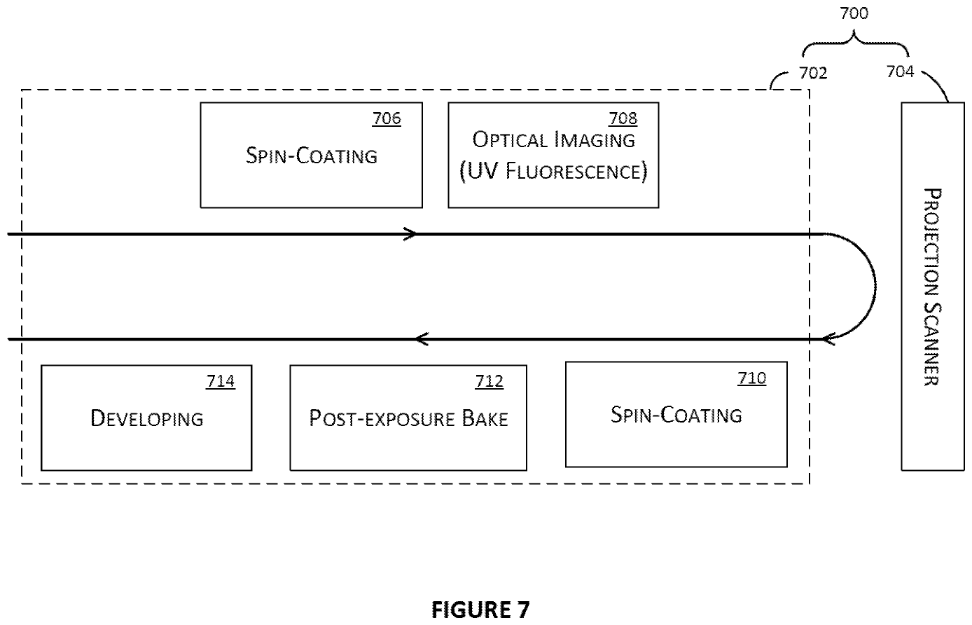

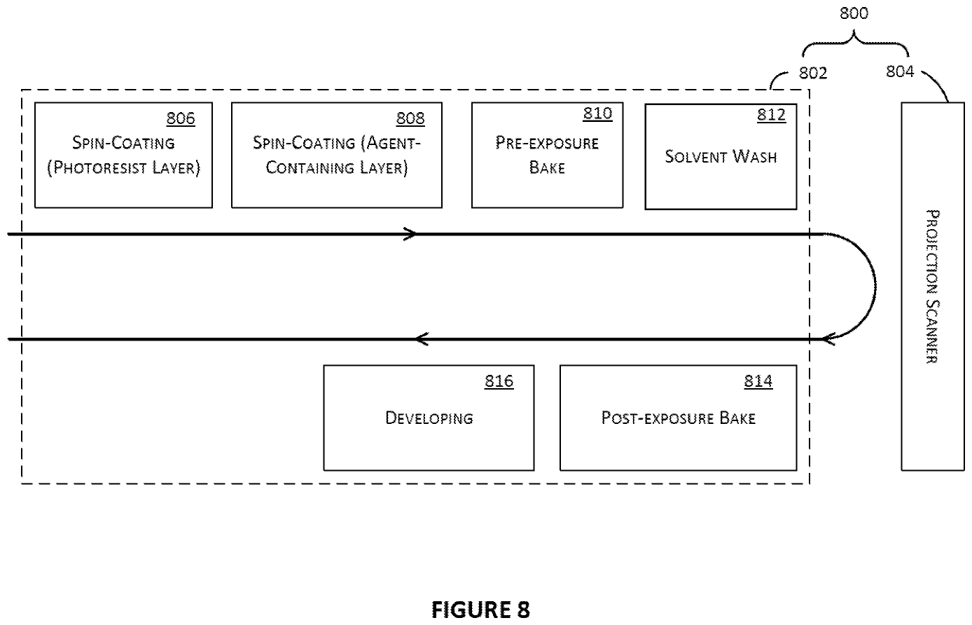

In certain embodiments, overcoat film 112 may be deposited in a deposition module (e.g., a spin-coating module) of a larger track system for a lithography process. An example lithography system that includes a track system is described in greater detail below with reference to FIGS. 7-8.

As shown in FIG. 1C, a bake 116 of semiconductor workpiece 100 may be performed. Baking semiconductor workpiece 100 may cause a solubility-changing agent 117 (e.g., acid) to diffuse into a portion of patterned structures 108 and to cause those portions of patterned structures 108 to become soluble in a developer.

For example, in the case of overcoat film 112 including a free acid, solubility-changing agent 117 may be the free acid and baking semiconductor workpiece 100 may cause the free acid to diffuse into a portion of patterned structures 108 and to cause those portions of patterned structures 108 to become soluble in a developer.

As another example, in the case of overcoat film 112 including a TAG as an agent-generating ingredient, baking semiconductor workpiece 100 may cause the TAG to generate solubility-changing agent 117 (e.g., acid), which may be referred to as activating the acid, cause the generated solubility-changing agent 117 to diffuse into a portion of patterned structures 108, and cause those portions of patterned structures 108 to become soluble in a developer.

As another example, in the case of overcoat film 112 including a PAG as an agent-generating ingredient, an exposure step that includes exposing overcoat film 112 to radiation may be performed prior to baking semiconductor workpiece 100. The exposure step may cause the PAG to generate solubility-changing agent 117 (e.g., acid), which may be referred to as activating the acid. Baking semiconductor workpiece 100 may cause the generated solubility-changing agent 117 to diffuse into a portion of patterned structures 108, and cause those portions of patterned structures 108 to become soluble in a developer.

Baking semiconductor workpieces 100 generally causes solubility-changing agent 117 to diffuse into a perimeter region of patterned structures 108 to a target depth, and to modify that perimeter region to be soluble in a developer, forming modified portions 118. For example, the modified perimeter regions (modified portions 118) may form a deprotected shell-like structure around patterned structures 108, consuming a portion of an outer perimeter of patterned structures 108 and thereby reducing both a vertical and lateral dimension of patterned structures 108. Among other factors, baking time and/or temperature may be optimized to control a depth of diffusion of the solubility-changing agent to achieve the target depth. The target depth, particularly on sidewall surfaces of patterned structures 108, may generally correspond to the target critical dimension of recesses in a structure being formed using process 102, as described further below in connection with FIG. 1G.

In certain embodiments, unmodified portions 119 of patterned structures 108 have a reduced height, shown as H₃, relative to the height H₂ of patterned structures 108 in FIG. 1A, and a difference between H₂ and H₃ represents a depth of diffusion of the solubility-changing agent, at least in a vertical dimension. In certain embodiments, the depth of diffusion, and resulting change in solubility of patterned structures 108, is approximately equal on all sides of patterned structures 108.

In certain embodiments, bake 116 may be performed by heating semiconductor workpiece 100 in a process chamber at a temperature between 50° C. to 250° C., for example between 60° C. to 140° C. in certain embodiments, in vacuum or under a gas flow. In a particular example, semiconductor workpiece 100 is baked for 1 to 3 minutes. The bake conditions of bake 116 may be selected to promote the diffusion of solubility-changing agent (and possibly generation of the solubility-changing agent from an agent-generating ingredient of overcoat film 112, if applicable) and associated change in solubility of a perimeter of patterned structures 108 to the target depth. This disclosure contemplates executing bake 116 in any suitable manner.

As illustrated in FIG. 1D, overcoat film 112 may be removed selectively from semiconductor workpiece 100, with minimal to no removal of modified portions 118 of patterned structures 108. This disclosure contemplates selectively removing overcoat film 112 in any suitable manner. In certain embodiments, overcoat film 112 may be removed selectively from semiconductor workpiece 100 using a suitable solvent or other developer.

As illustrated in FIG. 1E, an overcoat film 120 may be deposited on semiconductor workpiece 100. Overcoat film 120 may fill recesses 110 and cover patterned structures 108, including over modified portions 118 of patterned structures 108.

Overcoat film 120 may include a polymer that is capable of filling recesses 110. The material of overcoat film 120 may have a low dissolution rate in a chosen developer for revealing recesses 124, as described in greater detail below with reference to FIG. 1E. The material of overcoat film 120 also may be able to resist etching at a later stage to transfer a pattern into intermediate layer 106 (e.g., the pattern as defined in part by patterned structures 123, which include remaining portions of overcoat film 120, and recesses 124, and associated patterned transfer to be described in greater detail below with reference to FIGS. 1F-1G). In certain embodiments, the material of overcoat film 120 (e.g., a polymer) and formulation additives are soluble in one or more solvents that will have little to no intermixing with the underlying resist mandrel (e.g., patterned structures 108). Such polymer compositions may include a combination of monomer units including structures of moderate polarity such as hydroxy styrene, methyl methacrylate, and methyl acrylic acid. Additional formulation components at low (e.g., minimal) concentration may include quencher and/or photodecomposable base. Although overcoat film 120 is described as including particular materials, this disclosure contemplates overcoat film 120 including any suitable materials.

Overcoat film 120 may be deposited on semiconductor workpiece 100 in any suitable manner. For example, overcoat film 120 may be deposited by spin-coating, spray-coating, dip-coating, or roll-coating. As a particular example, overcoat film 120 may be deposited on semiconductor workpiece 100 using a spin-on deposition technique 114, in a similar manner to that described above with reference to FIG. 1B. Additionally or alternatively, overcoat film 120 may be deposited using a CVD, PECVD, ALD, or other suitable process.

In certain embodiments, overcoat film 120 may be deposited in a deposition module (e.g., a spin-coating module) of a larger track system for a lithography process. An example lithography system that includes a track system is described in greater detail below with reference to FIGS. 7-8.

As illustrated in FIG. 1F, modified portions 118 of patterned structures 108 and portions of overcoat film 120 may be removed selectively to reveal unmodified portions 119 of patterned structures 108 and remaining portions 122 of overcoat film 120. This disclosure contemplates removing modified portions 118 of patterned structures 108 and portions of overcoat film 120 in any suitable manner.

In certain embodiments, the portions of overcoat film 120 and modified portions 118 of patterned structures 108 are removed selectively using a developer. For example, the developer may remove a sufficient portion of overcoat film 120 to reveal modified portions 118 of patterned structures 108, and then remove those modified portions 118 of patterned structures 108 at a more rapid removal rate (e.g., dissolution rate). As a particular example, the developer may remove at a first removal rate a sufficient portion of overcoat film 120 to reveal modified portions 118 of patterned structures 108, and then remove modified portions 118 of patterned structures 108 at a greater second removal rate. In certain embodiments, the second removal rate is significantly larger than the first removal rate (1000:1, as a non-limiting example) such that once modified portions 118 of patterned structures 108 are revealed, modified portions 118 of patterned structures 108 are removed much more rapidly than additional removal of portions of overcoat film 120.

Removal of modified portions 118 of patterned structures 108 forms patterned structures 123 formed from unmodified portions 119 of patterned structures 108. Removal of modified portions 118 of patterned structures 108 reveals recesses 124 defined by remaining portions 122 of overcoat film 120 and patterned structures 123.

In the state illustrated in FIG. 1F, the combination of remaining portions 122 of overcoat film 120, patterned structures 123, and recesses 124 define a pattern that can be transferred to an underlying layer (e.g., intermediate layer 106). A difference between a width of a recess 124 (the critical dimension, or CD) and the adjacent structures (e.g., a remaining portion 122 of overcoat film 120 and a patterned structure 123) defines an aspect ratio. As described above, in general, a larger aspect ratio creates problems as recesses 124 are formed or when a patterned defined by the recesses 124 and adjacent structures is transferred to an underlying layer. These problems can lead to pattern collapse, surface roughness, lack of fidelity to a target critical dimension, and/or other problems. Thus, minimizing an aspect ratio defined by remaining portions 122 of overcoat film 120, patterned structures 123, and recesses 124 may be desirable.

Certain embodiments of this disclosure provide techniques for forming semiconductor workpiece 100 at the state illustrated in FIG. 1A. Thus, in certain embodiments, techniques described herein may be incorporated into a larger patterning process (e.g., process 102) for forming sub-resolution features. This disclosure provides example processes for reducing a height of structures patterned from photoresist (e.g., patterned structures 108) to a height H₂ as part of forming semiconductor workpiece 100 at the state illustrated in FIG. 1A. That is, the patterning process used to form patterned structures 108 shown in FIG. 1A is implemented according to the concepts described in this disclosure, which results in a height (H₂) of patterned structures 108 being reduced prior to performing subsequent steps of patterning process 102. Performing a height reduction at this stage may reduce an aspect ratio of a pattern defined using further steps of process 102 to produce recesses 124. Furthermore, the height reduction of structures patterned from photoresist (e.g., patterned structures 108) may be accomplished with little to no impact on an ability to accurately pattern structures from photoresist (e.g., patterned structures 108).

As shown in FIG. 1F, patterned structures 123 have a reduced height H₃ that is less than a height (H₂) of patterned structures 108 (see FIG. 1A) and less than a height (H₁) of a photoresist layer from which semiconductor structures were formed (see FIGS. 2A and 3A, described below). This reduced height H₃ may be due at least in part to the manner in which semiconductor workpiece 100 is formed at the state illustrated in FIG. 1A (e.g., using patterning process 202 of FIGS. 2A-2E or patterning process 302 of FIGS. 3A-3G). Recesses 124 have a lateral width, which may be referred to as the critical dimension (labeled as CD). This critical dimension (lateral width of recesses 124) may be the target critical dimension of process 102. In certain embodiments, the reduced height H₃ provides an improved ability to achieve the desired critical dimension of recesses 124.

Although heights of patterned structures 123 are shown to vary (e.g., heights of remaining portions 122 of overcoat film 120 are shown to be greater than heights of unmodified portions 119 of patterned structures 108), this disclosure contemplates remaining portions 122 of overcoat film 120 and unmodified portions 119 of patterned structures 108 having the same or different heights. In certain embodiments, processing conditions and formulation chemistry may be tuned to planarize and/or minimize discrepancies in heights of remaining portions 122 of overcoat film 120 and heights of unmodified portions 119 of patterned structures 108.

As illustrated in FIG. 1G, the pattern defined by the combination of remaining portions 122 of overcoat film 120, patterned structures 123, and recesses 124 may be transferred to intermediate layer 106. This pattern transfer may be performed using any suitable combination of etch processes, including any suitable wet etch process and dry etch processes. For example, the etch process may include one or more of aa liquid etch, a chemical wet etch, a chemical dry etch, a plasma etch, an atomic layer etch, or other suitable etch process. In the illustrated example, transferring the pattern defined by the combination of remaining portions 122 of overcoat film 120, patterned structures 123, and recesses 124 to intermediate layer 106 includes extending recesses 124 into intermediate layer 106. Due at least in part to the improved CD of recesses 124 and/or the reduced height H₃, certain embodiments improve pattern transferring fidelity in transferring the pattern to the underlying layer (e.g., intermediate layer 106).

Turning to FIGS. 2A-2E and 3A-3G, certain embodiments provide techniques for reducing a height of a photoresist layer that include reducing a height of the photoresist layer subsequent to exposing a semiconductor workpiece (e.g., including the photoresist layer) to a pattern of actinic radiation as part of a process for patterning the photoresist layer (e.g., into one or more semiconductor structures). Such an example is illustrated in and described in connection with FIGS. 2A-2E. Certain embodiments provide techniques for reducing a height of a photoresist layer that include reducing a height of the photoresist layer prior to exposing a semiconductor workpiece (e.g., including the photoresist layer) to a pattern of actinic radiation as part of a process for patterning the photoresist layer (e.g., into one or more semiconductor structures). Such an example is illustrated in and described in connection with FIGS. 3A-3G.

For brevity and clarity, this description adopts a convention in which elements adhering to the pattern [x02] may be related implementations of a process and/or semiconductor workpiece in certain embodiments. For example, except as otherwise stated or readily apparent, semiconductor workpiece 200 may be similar to semiconductor workpiece 100, substrate 204 may be similar to substrate 104, and the like. An analogous convention has also been adopted for other elements as made clear by the use of similar terms in conjunction with the described three-digit numbering system. Through this convention, where applicable, features that have already been described are incorporated by reference without being repeated.

FIGS. 2A-2E illustrate cross-sectional views of an example semiconductor workpiece 200 during an example patterning process 202, according to certain embodiments. In the example illustrated FIGS. 2A-2E, a height of a photoresist layer is reduced subsequent to exposing semiconductor workpiece 200 (e.g., including a photoresist layer) to a pattern of actinic radiation, but prior to development of the photoresist layer.

As shown in FIG. 2A, a semiconductor workpiece 200 may be formed that includes an intermediate layer 206 formed over a substrate 204 and a photoresist layer 209 formed over intermediate layer 206. For example, intermediate layer 206 may be disposed on substrate 204 and photoresist layer 209 may be disposed on intermediate layer 206.

Photoresist layer 209 may include any suitable type of layer that may be used to form a masking layer for patterning intermediate layer 206, and may be made of a suitable material for acting as a photoresist. Photoresist layer 209 is a layer to be patterned by an exposure, such as by using an exposure module, which may be referred to as a scanner or stepper, and subsequent development step to form patterned features. For example, photoresist layer 209 may include a light-sensitive material made of a polymer, a solvent, and a sensitizer. The polymer is designed to change its structure when exposed to actinic radiation. The solvent allows the material of photoresist layer 209 to be spun to form a thin layer on an underlying layer (e.g., intermediate layer 206). The sensitizer (or inhibitor) controls the photoreaction in a polymer phase.

For example, photoresist layer 209 can be a chemically-amplified resist (CAR). As another example, photoresist layer 209 may be a metal-based resist material such as an organometallic material such as a metal oxide (MOx) photoresist. The lithography technology used to pattern a photoresist layer to form patterned structures 108 may have an associated resolution consistent with the wavelength of radiation implemented using that lithography technology. Such photolithography technologies may include immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), EUV lithography, deep ultraviolet (DUV) lithography, or any suitable photolithography. Additionally, the lithography technology may be mask-based (e.g., projection lithography), maskless (e.g., electron beam (e-beam) lithography), or another suitable type of lithography.

The photoresist material of photoresist layer 209 may be appropriate for the type of photolithography technology to be used to pattern the photoresist layer 209. The photoresist material of photoresist layer 209 may be a positive photoresist or a negative photoresist. For a positive photoresist, areas of photoresist layer 209 that the semiconductor fabricator intends to remove (and that generally correspond to areas of an underlying layer that will be removed using the structures patterned from photoresist layer 209 as an etch mask) are exposed to the UV light. The UV light changes the chemical structure of the exposed areas of the photoresist such that the exposed areas become more soluble in a developer solvent that can be used to remove the exposed areas in a development processing stage while the areas of the photoresist that are not exposed remain. For a negative photoresist, portions of photoresist layer 209 that are exposed to UV polymerize, crosslink, network, or otherwise change chemical composition making the exposed regions less soluble to the developer solution while non-exposed regions can be removed using the developer solution.

In certain embodiments, photoresist layer 209 may include an agent-generating ingredient (e.g., a PAG) that releases a solubility-changing agent (acid, or photoacid) in response to UV light exposure. The generated acid may induce further chemical reactions in photoresist layer 209, which may improve the tonality in the patterned version of photoresist layer 209.

Photoresist layer 209 may be deposited in any suitable manner. For example, photoresist layer 209 may be deposited by spin-coating, spray-coating, dip-coating, or roll-coating. As a particular example, photoresist layer 209 may be deposited on semiconductor workpiece 100 using a spin-on deposition technique 214, which also may be referred to as spin-coating. Example details of example techniques for spin-on deposition are described above in connection with spin-on deposition technique 114, and that description is incorporated by reference.

In certain embodiments, photoresist layer 209 is deposited on intermediate layer 206 in a deposition module (e.g., a spin-coating module) of a larger track system for a lithography process. An example lithography system that includes a track system is described in greater detail below with reference to FIGS. 7-8. It should be understood, however, that photoresist layer 209 may be deposited using any suitable dry or wet process.

In certain embodiments, a top coat 226 is formed on a top surface of photoresist layer 209. Top coat 226 could serve any suitable purpose. As one example, when an immersion lithography technique is used to pattern photoresist layer 209, top coat 226 may serve as a diffusion barrier to inhibit diffusion into photoresist layer 209 of a liquid that serves as a lensing agent during immersion lithography. In certain embodiments, top coat 226 may have an ability to coat on top of a photoresist material with little to no impact on the photoresist to otherwise function, and an ability to be stripped prior to photoresist development or be removed during photoresist development with little to no impact on photoresist functionality. As just one example, top coat 226 may include a fluorinated polymer.

Top coat 226 may be deposited on semiconductor workpiece 200 in any suitable manner.

For example, top coat 226 may be deposited in a separate deposition step subsequent to deposition of photoresist layer 209. As a particular example, top coat 226 may be deposited in a separate spin-coating process, potentially in a separate, on-track spin-coating module.

As another example, photoresist layer 209 and top coat 226 may be deposited as part of a single deposition step. As a particular example, photoresist components to be formed into photoresist layer 209 and top-coat components to be formed into top coat 226 may be combined in appropriate relative amounts into a single formula (e.g., dissolved in a solution together). The formula may be designed such that the photoresist components and top-coat components self-segregate when deposited on a surface of semiconductor workpiece 200 (e.g., on a surface of intermediate layer 206). For example, a spin-coating technique (e.g., similar to spin-on deposition technique 214) may cause the photoresist components to be deposited on intermediate layer 206 to form photoresist layer 209, while the spin-coating technique causes top-coat components to rise to the top and form top coat 226 on photoresist layer 209. During the spin-coating process (including associated process conditions, such as temperature and spin-rate), the photoresist components may be attracted to the surface materials of intermediate layer 206 while the top-coat components may be attracted to the environment above semiconductor workpiece 200 (e.g., air), resulting in separation of the photoresist components and the top-coat components into photoresist layer 209 and top coat 226. Thus, in certain embodiments, a single deposition may result in top coat 226 formed on photoresist layer 209.

Furthermore, because top coat 226 is formed over photoresist layer 209 prior to exposure (irradiation) of photoresist layer 209, top coat 226 may be relatively transparent to the actinic radiation that will be used to irradiate a portion of photoresist layer 209. This additional consideration also may affect selection of materials for top coat 226.

Initially photoresist layer 209 may have any suitable thickness, referred to throughout this disclosure as height (labeled as H₁). The height H₁ may refer to the thickness of photoresist layer 209 as deposited or after any suitable pre-patterning processing, such as any planarization or other smoothing processing. The height H₁ may be optimized to, during an exposure step, take advantage of the full aerial image and photons to which photoresist layer 209 is being exposed. In other words, in certain embodiments, simply depositing a thinner photoresist layer 209 is not optimal or practical to provide a thinner patterned structure (e.g., patterned structures 108), as it may negatively impact lithographic performance. Depositing a thinner photoresist layer 209 (or otherwise thinning photoresist layer 209) prior to exposure may result in a photoresist layer 209 of non-optimized height during exposure, which may cause a loss in the patterning of photoresist layer 209, including non-optimal profile, surface roughness, and the like.

In certain embodiments, photoresist layer 209 has a thickness of 5 nm to 5 μm, for example 20 nm to 1 μm. Appropriate thickness values may be driven, in part, by the photolithography technology being used to pattern photoresist layer 209. It should be understood that these thickness values are provided as examples only, and that photoresist layer 209 may have any suitable thickness.

As shown in FIG. 2B, photoresist layer 209 is exposed to a pattern of actinic radiation 228 (is irradiated) to form a pattern in photoresist layer 209. This may be referred to as an exposure phase of a photolithography process. For example, actinic radiation 228 may be directed toward semiconductor workpiece 200, and particularly to a surface of photoresist layer 209, through a patterned mask 230 to cause a target pattern to form in photoresist layer 209. The target pattern may include exposed regions 232 and non-exposed regions 234. Depending on whether a positive photoresist or a negative photoresist is used, exposed regions 232 of photoresist layer 209 may be designed to be removed or to remain when photoresist layer 209 is developed in a later step. In the illustrated example, as will be shown in connection with FIGS. 2D-2F, exposed regions 232 are designed to be removed such that a pattern of patterned mask 230 corresponds to the target pattern to be formed in photoresist layer 209.

As described above, photoresist layer 209 may include an agent-generating ingredient that is configured to generate a solubility-changing agent in response to a suitable energy (e.g., actinic radiation 228). For example, the agent-generating ingredient in photoresist layer 209 may be a PAG. In response to exposure to actinic radiation 228, the agent-generating ingredient (e.g., the PAG) in exposed regions 232 of photoresist layer 209 may generate a solubility-changing agent 236 (e.g., acid) in exposed regions 232.

The lithography technology used for the exposure phase of patterning process 202 may include any of the above-described lithography technologies, or any other suitable lithography technology. In certain embodiments, semiconductor workpiece 200 is transferred from the above-described track system to an exposure module (which also may be referred to as a stepper module or scanner module) for exposing photoresist layer 209 to the pattern of actinic radiation 228. An example lithography system that includes a projection scanner is described in greater detail below with reference to FIG. 7.

As illustrated in FIG. 2C, an agent-containing layer 238 may be deposited on semiconductor workpiece 200 (e.g., over photoresist layer 209) using various deposition techniques, including any suitable dry or wet deposition process. For example, agent-containing layer 238 may be deposited by spin-coating, spray-coating, dip-coating, or roll-coating. As a particular example, agent-containing layer 238 may be deposited on semiconductor workpiece 200 (e.g., over photoresist layer 209) using a spin-on deposition technique 214 similar to that described above for FIG. 2A, the details of which are incorporated by reference.

Agent-containing layer 238 may be deposited to facilitate reducing a thickness (e.g., a height) of photoresist layer 209 and ultimately semiconductor structures (e.g., analogous to patterned structures 108) formed from photoresist layer 209. Agent-containing layer 238 also may be referred to as a trimming layer given the role of agent-containing layer 238 in trimming a thickness/height of photoresist layer 209 and ultimately semiconductor structures (e.g., analogous to patterned structures 108) formed from photoresist layer 209.

The agent of agent-containing layer may be the agent itself or an agent-generating ingredient that is configured to generate the agent in response to a suitable agent-activation trigger (e.g., heat or radiation). The agent may be a substance that is configured to change the solubility of a material in which the agent is disposed in response to a suitable trigger (e.g., heat), and thus may be referred to as a solubility-changing agent. For example, the solubility-changing agent may be configured to change a solubility of agent-containing layer 238 and, as described in greater detail below with reference to FIG. 2D, a portion of photoresist layer 209.

Agent-containing layer 238 may be a multicomponent material that, as deposited, includes a first component and a second component. The first component could be, for example, a polymer. The second component could be, for example, the solubility-changing agent, such as an acid (e.g., a free acid). The second component could be, as another example, an agent-generating ingredient that, in response to a suitable agent-activation trigger (e.g., heat or radiation), generates a solubility-changing agent (e.g., an acid). Example agent-generating ingredients may include a TAG or a PAG.

Continuing with the example of FIGS. 2A-2E, agent-containing layer 238 is deposited subsequent to exposing semiconductor workpiece 200 (e.g., including photoresist layer 209) to the pattern of actinic radiation 228, as well as prior to executing a post-exposure bake (PEB), as described below with reference to FIG. 2D. In certain embodiments, agent-containing layer 238 can remain on semiconductor workpiece 200 (e.g., on photoresist layer 209) through the PEB with little or no impact on the lithographic performance, possibly other than reducing a thickness of non-exposed regions 234 of photoresist layer 209, before removing agent-containing layer 238 during a later phase (e.g., prior to or during a development phase).

In certain embodiments, depending on the configuration and capabilities of the apparatuses involved, and to the extent semiconductor workpiece 200 has not already been transferred back to a track system, depositing agent-containing layer 238 may be performed in the exposure system or by another deposition system separate from the exposure system and the track system, or may be performed after transferring semiconductor workpiece 200 from the exposure system back to the track system such that depositing agent-containing layer 238 (e.g., using spin-on deposition technique 214) is performed by a suitable deposition module of the track system.

Agent-containing layer 238 may have any suitable thickness. In certain embodiments, agent-containing layer 238 has a thickness of 1 nm to 100 nm, for example 20 nm to 70 nm. It should be understood that these thickness values are provided as examples only, and that agent-containing layer 238 may have any suitable thickness.

As illustrated in FIG. 2D, a PEB 240 may be performed to modify portions of photoresist layer 209 to be soluble for development. For example, PEB 240 may modify portions of photoresist layer 209 to be soluble in one or more developers for removing those portions of photoresist layer 209 from semiconductor workpiece 200. The portions of photoresist layer 209 that PEB 240 modifies to become soluble for development may include exposed regions 232 of photoresist layer 209 and top portions 242 of non-exposed regions 234 of photoresist layer 209 (top portions 242 being shown in ghost mode using dashed lines). PEB 240 may accomplish this solubility change in multiple ways.

For example, with the exposure process executed at the stage illustrated in FIG. 2B, solubility-changing agent 236 (e.g., acid) has been activated or otherwise generated in exposed regions 232 of photoresist layer 209. PEB 240 may cause solubility-changing agent 236 to react with other substances (e.g., a polymer) of exposed regions 232 to cause exposed regions 232 to become soluble for development. For example, PEB 240 may cause solubility-changing agent 236 to convert one or more of the pendant groups of another substance (e.g., a polymer) of exposed regions 232 to cause exposed regions 232 to become soluble for development. This process also may be referred to as a deprotection reaction that causes exposed regions 232 to become deprotected (e.g., soluble/removable) in a given developer.

As another example, PEB 240 may cause a solubility-changing agent 244 to diffuse from agent-containing layer 238 to top portions 242 of non-exposed regions 234 of photoresist layer 209. The heat associated with PEB 240 may cause solubility-changing agent 244 to react with other substances (e.g., a polymer) of top portions 242 of non-exposed regions 234 to cause top portions 242 of non-exposed regions 234 to become soluble for development. For example, in a similar type of deprotection reaction, PEB 240 may cause solubility-changing agent 244 to convert one or more of the pendant groups of another substance (e.g., a polymer) of top portions 242 of non-exposed regions 234 to cause top portions 242 of non-exposed regions 234 to become soluble for development in a given developer.

In certain embodiments, agent-containing layer 238 includes solubility-changing agent 244 as deposited. For example, in an implementation in which solubility-changing agent 244 is an acid, solubility-changing agent 244 could be a free acid included in agent-containing layer 238 as deposited.

In certain embodiments, agent-containing layer 238 includes an agent-generating ingredient that generates solubility-changing agent 244 in response to a suitable agent-activation trigger (e.g., heat or radiation). For example, in an implementation in which solubility-changing agent 244 is an acid, the agent-generating ingredient may include a TAG or a PAG, which may be included in agent-containing layer 238 as deposited.

In the case of a TAG, the TAG may generate solubility-changing agent 244 (e.g., acid) in response to heat. For example, the heat associated with PEB 240 may cause the TAG to generate solubility-changing agent 244 within agent-containing layer 238. Thus, in certain embodiments, the heat associated with PEB 240 both causes the agent-generating ingredient (e.g., a TAG) in agent-containing layer 238 to generate solubility-changing agent 244 within agent-containing layer 238 and causes the generated solubility-changing agent 244 to diffuse into and change the solubility of suitable portions of photoresist layer 209 (e.g., top portions 242 of non-exposed regions 234 of photoresist layer 209). Of course, this disclosure contemplates the heat for causing the TAG (or other suitable agent-generating ingredient) to generate solubility-changing agent 244 in a step separate from PEB 240, if appropriate.

In the case of a PAG, the PAG may generate solubility-changing agent 244 (e.g., acid) in response to radiation. For example, agent-containing layer 238 may be exposed to radiation to cause the PAG to generate solubility-changing agent 244 within agent-containing layer 238. In certain embodiments, a separate irradiation step is introduced into a track-based process to irradiate agent-containing layer 238, causing the PAG to generate solubility-changing agent 244 within agent-containing layer 238. Subsequently, semiconductor workpiece 200 may be moved to a module for executing PEB 240, and PEB 240 causes the generated solubility-changing agent 244 to diffuse into and change the solubility of suitable portions of photoresist layer 209 (e.g., top portions 242 of non-exposed regions 234 of photoresist layer 209).

Of course, this disclosure contemplates including other suitable types of agent-generating ingredients that generate solubility-changing agent 244 in response to a suitable activation trigger (e.g., heat, radiation, or another suitable trigger), if appropriate.

In certain embodiments, diffusion of solubility-changing agent 244 from agent-containing layer 238 to top portions 242 of photoresist layer 209 primarily moves in a downward direction (as indicated by the downward arrows into top portions 242 in FIG. 2D) due to a concentration gradient of solubility-changing agent 244 between agent-containing layer 238 and non-exposed regions 234 of photoresist layer 209. In other words, during PEB 240, solubility-changing agent 244 in agent-containing layer 238 drives toward areas of lower concentration of solubility-changing agent 244, which in particular includes top portions 242 of non-exposed regions 234. Additionally, exposed regions 232 of photoresist layer 209, which are adjacent to non-exposed regions 234, already included solubility-changing agent 236, which may be similar or identical to solubility-changing agent 244, meaning that exposed regions 232 of photoresist layer 209 may operate as higher concentration areas of photoresist layer 209, which may further drive diffusion of solubility-changing agent 244 toward the low-concentration top portions 242 of non-exposed regions 234, further giving the diffusion of solubility-changing agent 244 primarily a vertical component into top portions 242.

In certain embodiments, one or more properties of agent-containing layer 238 may be selected to achieve a desired level of diffusion of solubility-changing agent 244 (e.g., acid) into certain portions of photoresist layer 209 (e.g., into non-exposed regions 234 of photoresist layer 209) to cause those portions of photoresist layer 209 to become soluble for subsequent development. The desired level of diffusion could be, for example, a target depth of diffusion into non-exposed regions 234 of photoresist layer 209 to ultimately cause a thinning, or reduction in height, of non-exposed regions 234 of photoresist layer 209 by the amount of the target depth. The one or more properties of agent-containing layer 238 may include the materials of agent-containing layer 238 (e.g., including a polymer and an agent or agent-generating ingredient), a concentration of solubility-changing agent 244 (e.g., acid) in agent-containing layer 238, a thickness of agent-containing layer 238, and/or other suitable parameters.

Additionally, while temperature and/or bake time associated with PEB 240 may be adjusted to affect the depth of diffusion of solubility-changing agent 244 into non-exposed regions 234 and associated solubility change, adjusting temperature and/or bake time associated with PEB 240 may undesirably alter other aspects of the patterning of photoresist layer 209, such as a lateral critical dimension of non-exposed regions 234. Thus, in certain embodiments, it may be desirable for temperature and/or bake time associated with PEB 240 to remain optimized for patterning photoresist layer 209 (e.g., a lateral critical dimension of non-exposed regions 234). Nonetheless, this disclosure contemplates adjusting the temperature and/or bake time associated with PEB 240 to achieve a desired depth of diffusion and solubility change, if appropriate.

One or more of acid composition (e.g., molecular weight and sterics), polymer composition (e.g., polarity) and film density, bake temperature (e.g., of PEB 240), bake time (e.g., of PEB 240), and a possible presence of a quencher in the film to be reacted may affect the depth of diffusion of solubility-changing agent 244 and associated solubility change. From relatively higher to relatively lower diffusivity, acids of composition may include triflic acid, nonaflic acid, and p-Toluenesulfonic acid. These considerations also may apply to other depth-of-diffusion determinations in other figures of this disclosure.

Bottom portions 248 of non-exposed regions 234 of photoresist layer 209 may remain insoluble for development during a development phase of patterning process 202. Bottom portions 248 also may be referred to as remaining portions of photoresist layer 209 (e.g., remaining, following development at a subsequent stage). Bottom portions 248 may have a reduced thickness relative to a thickness of photoresist layer 209 at earlier stages of process 202. For example, a height (H₂) of bottom portions 248 may be less than a height (H₁) of photoresist layer 209 as deposited at the stage illustrated in FIG. 2A.

The difference between H₁ and H₂ may be the depth (D) that solubility-changing agent 244 penetrated into non-exposed regions 234 of photoresist layer 209 to cause the solubility change in those non-exposed regions 234 (e.g., top portions 242). The depth of diffusion of solubility-changing agent 244 into non-exposed regions 234 may be deliberately designed and controlled to achieve a desired thickness reduction/height (H₂). Thus, the use of agent-containing layer 238 may allow high degree of control of a height reduction of non-exposed regions 234 of photoresist layer 209, and ultimately to patterned structures (e.g., analogous to patterned structures 208) formed from photoresist layer 209. In certain embodiments, a process designer may attempt to achieve a desired level of diffusion and associated solubility change, and thereby associated height reduction of non-exposed regions 234 such that sufficient mask budget for pattern transfer exists in the patterned structures being formed. In certain embodiments, the height reduction achieves an aspect ratio (structure height to recess width) of 5:1 or less, such as 2:1. It should be understood, however, that this disclosure contemplates reducing heights of patterned structures 208 by any suitable amount.

It should be understood that the heights H₁, H₂, and the like in the FIGS. 1A-1G, 2A-2E, 3A-3G, and/or other figures might or might not be the same. As just one example, H₂ in FIG. 1C might or might not be the same as H₂ in FIG. 2D.

In certain embodiments, PEB 240 may be performed by heating semiconductor workpiece 200 in a process chamber at a temperature between 50° C. to 250° C., for example between 60° C. to 140° C., in vacuum or under a gas flow. In a particular example, semiconductor workpiece 200 is baked for 1 to 3 minutes. The PEB bake conditions may be selected to promote a degree of crosslinking in the exposed resist for improved contrast and reduced line edge roughness (LER). This disclosure contemplates executing PEB 240 in any suitable manner.

In certain embodiments, to the extent semiconductor workpiece 200 has not already been transferred back to a track system as part of depositing agent-containing layer 238 (e.g., using spin-on deposition technique 214), semiconductor workpiece 200 may be transferred from the exposure system back to the track system such that PEB 240 is performed by a suitable module of the track system.

As illustrated in FIG. 2E, in a developing phase, photoresist layer 209 may be developed using a suitable development process to remove soluble portions of photoresist layer 209. During the developing phase, and according to the illustrated example of a positive photolithography process, soluble portions of photoresist layer 209 may be removed using a suitable dry etch or wet etch process, and thereby forming photoresist layer 209 into a mask according to pattern mask 230 that can then be used to perform further fabrication process, such as may be associated with patterning process 102 of FIGS. 1A-1F.

The soluble portions of photoresist layer 209 that are removed during the development phase may include exposed regions 232 of photoresist layer 209 and top portions 242 of non-exposed regions 234 of photoresist layer 209. Following removal of soluble portions of photoresist layer 209, bottom portions 248 of non-exposed regions 234 of photoresist layer 209 remain and form semiconductor structures 208. Additionally, removal of soluble portions of photoresist layer 209, and particularly exposed regions 232, forms recesses 210 in photoresist layer 209. Recesses 210 in photoresist layer 209 may be used in an etching process (e.g., patterning process 102 of FIGS. 1A-1G) to etch features in intermediate layer 206. Recesses 210 may have a lateral width (W). Recesses 210 may have the same or different widths in any suitable combination.

Semiconductors structures 208 have a reduced height H₂ relative to an initial height H₁ of photoresist layer 209. The height reduction (H₁-H₂) may corresponding to a depth D of top portions 242, which are removed as part of the development process. This height reduction, which also may be referred to as a thickness reduction, may reduce an aspect ratio (height of semiconductor structure 208:width of adjacent recess 210) in semiconductor workpiece 200. This reduction in aspect ratio may persist (although not necessarily by a same amount) as the pattern formed by semiconductor structures 208 is used as part of a patterning process to pattern underlying layers. For example, using semiconductor workpiece 200 at the state illustrated in FIG. 2E as semiconductor workpiece 100 at the stage illustrated in FIG. 1A in connection with the anti-spacer patterning process 102 illustrated in FIGS. 1A-1F (and subsequent pattern transfer illustrated in FIG. 1G), the reduction in aspect ratio associated with the pattern defined by semiconductor structures 208 may result in a reduction in aspect ratio at a later stage of process 102 (e.g., at the stage illustrated in FIG. 1F).

In certain embodiments, soluble portions of photoresist layer 209 may be removed in a wet process by treating semiconductor workpiece 200 with a developer solution to dissolve the soluble portions of photoresist layer 209. The appropriate developer solution for removing soluble portions of photoresist layer 209 depends in part on the material of photoresist layer 209. In certain embodiments, the developer solution may include an aqueous alkaline solution that includes a water-soluble organic base. As particular examples, the developer solution may include tetramethylammonium hydroxide (TMAH).

Alternatively, a dry process may be used in other embodiments. The dry process may include, for example, a selective plasma etch process or a thermal process, which may eliminate the use of a developing solution. In certain embodiments, the dry process may be performed using RIE or atomic layer etching (ALE).

As illustrated in FIG. 2E, the developing phase also includes removing agent-containing layer 238 (and top coat 226, if applicable) from photoresist layer 209. In certain embodiments, the process/chemistry that is used to develop photoresist layer 209 (e.g., to remove soluble portions of photoresist layer 209) also may be capable of removing the material of agent-containing layer 238 (and top coat 226, if applicable). In another example, agent-containing layer 238 (and top coat 226, if applicable) may be removed from semiconductor workpiece 200 prior to developing photoresist layer 209 using a removal process that selectively removes agent-containing layer 238 (and top coat 226, if applicable). This disclosure contemplates performing the development phase using any suitable process/chemistry.

For example, development of photoresist layer 209 (e.g., to remove soluble portions of photoresist layer 209 and potentially agent-containing layer 238, and top coat 226, if applicable) may be performed using an organic solvent. Potential example organic solvents may include propylene glycol methyl ether acetate (PGMEA), 2-Heptanone, isopropyl alcohol (IPA), 2-Pentanone, or another suitable organic solvent. In one example, the solvent dispense volume may be between 5 ml to 500 ml, for example 10 ml to 100 ml. The substrate (e.g., workpiece 200) may be secured to a rotating chuck that supports the substrate. The rotating speed during liquid dispense can be between 50 rpm to 3000 rpm, for example 1000 rpm to 2000 rpm. Although organic solvents are primarily described, this disclosure contemplates using any suitable solvent.

As another example, development of photoresist layer 209 (e.g., to remove soluble portions of photoresist layer 209 and potentially agent-containing layer 238, and top coat 226, if applicable) may be performed in a gas phase with or without plasma. Example gases for such a gas phase may include hydrobromic acid (HBr), boron trichloride (BCL3), or another suitable gas/gas combination.

FIGS. 3A-3G illustrate cross-sectional views of an example semiconductor workpiece 300 during an example patterning process 302, according to certain embodiments. In the example illustrated FIGS. 3A-3G, an agent-containing layer is used to modify a portion of photoresist layer to become soluble for development prior to exposing semiconductor workpiece 300 (e.g., including a photoresist layer) to a pattern of actinic radiation for patterning the photoresist layer.

As shown in FIG. 3A, a semiconductor workpiece 300 may be formed that includes an intermediate layer 306 formed over a substrate 304 and a photoresist layer 309 formed over intermediate layer 306. For example, intermediate layer 306 may be disposed on substrate 304 and photoresist layer 309 may be disposed on intermediate layer 306. In certain embodiments, a top coat 326 is formed on photoresist layer 309.

As illustrated in FIG. 3B, an agent-containing layer 338 may be deposited on semiconductor workpiece 300 (e.g., over photoresist layer 309) using a suitable deposition technique, including any suitable dry or wet deposition process. For example, agent-containing layer 338 may be deposited by spin-coating, spray-coating, dip-coating, or roll-coating. As a particular example, agent-containing layer 338 may be deposited on semiconductor workpiece 300 (e.g., over photoresist layer 309) using a spin-on deposition technique 314. Spin-on deposition technique 314 may be similar to spin-on deposition technique 214, the description of which is incorporated by reference.

Agent-containing layer 338, a manner of depositing agent-containing layer 338, and other associated considerations may be similar to those described above in connection with agent-containing layer 238, described above in association with FIG. 2C, the description of which is incorporated by reference.

In certain embodiments, depending on the configuration and capabilities of the apparatuses involved, deposition of agent-containing layer 338 may be performed in a same deposition module (e.g., a spin-on deposition module) of the track system as was used to deposit photoresist layer 309 or in a separate deposition module of the track system than the one used to deposit photoresist layer 309. Alternatively, semiconductor workpiece 300 may be transferred from the track system to another deposition system for depositing agent-containing layer 338.

As illustrated in FIG. 3C, a pre-exposure bake 350 may be performed to cause a solubility-changing agent 344 to diffuse into portions of photoresist layer 309. The portions of photoresist layer 309 into which solubility-changing agent 344 diffuses may be at least some of the portions of photoresist layer 309 that are removed in a subsequent development step, and may particularly include a portion of photoresist layer 309 that reduces a height of patterned structures formed from photoresist layer 309.

For example, pre-exposure bake 350 may cause a solubility-changing agent 344 to diffuse from agent-containing layer 338 to first portion 352 of photoresist layer 309 such that photoresist layer 309 includes first portion 352 into which solubility-changing agent 344 has diffused and a second portion 354 beyond the diffusion region of photoresist layer 309. First portion 352 may be disposed between agent-containing layer 338 and second portion 354. For example, first portion 352 may be a top portion of photoresist layer 309 and second portion 354 may be a bottom portion of photoresist layer 309.

In certain embodiments, agent-containing layer 338 includes solubility-changing agent 344 as deposited. For example, in an implementation in which solubility-changing agent 344 is an acid, solubility-changing agent 344 could be a free acid included in agent-containing layer 338 as deposited.

In certain embodiments, agent-containing layer 338 includes an agent-generating ingredient that generates solubility-changing agent 344 in response to a suitable activation trigger (e.g., heat or radiation). For example, in an implementation in which solubility-changing agent 344 is an acid, the agent-generating ingredient may include a TAG or a PAG, which may be included in agent-containing layer 338 as deposited.

In the case of a TAG, the TAG may generate solubility-changing agent 344 (e.g., acid) in response to heat. For example, the heat associated with pre-exposure bake 350 may cause the TAG to generate solubility-changing agent 344 within agent-containing layer 338. Thus, in certain embodiments, the heat associated with pre-exposure bake 350 both causes the agent-generating ingredient (e.g., a TAG) in agent-containing layer 338 to generating solubility-changing agent 344 within agent-containing layer 338 and causes the generated solubility-changing agent 344 to diffuse into suitable portions of photoresist layer 309 (e.g., first portion 352). Of course, this disclosure contemplates the heat for causing the TAG or other suitable agent-generating ingredient to generate solubility-changing agent 344 in a step separate from pre-exposure bake 350, if appropriate.

In the case of a PAG, the PAG may generate solubility-changing agent 344 (e.g., acid) in response to radiation. For example, agent-containing layer 338 may be exposed to radiation to cause the PAG to generate solubility-changing agent 344 within agent-containing layer 338. Thus, in certain embodiments, a separate irradiation step is introduced into a track-based process to irradiate agent-containing layer 338, causing the PAG to generate solubility-changing agent 344 within agent-containing layer 338. Subsequently, semiconductor workpiece 300 may be moved to a module for executing pre-exposure bake 350, and pre-exposure bake 350 causes the generated solubility-changing agent 344 to diffuse into suitable portions of photoresist layer 309 (e.g., first portion 352).

Of course, this disclosure contemplates including other suitable types of agent-generating ingredients that generate solubility-changing agent 344 in response to a suitable agent-activation trigger (e.g., heat, radiation, or another suitable trigger), if appropriate.

In certain embodiments, diffusion of solubility-changing agent 344 from agent-containing layer 338 to first portions 352 of photoresist layer 309 primarily moves in a downward direction (as indicated by the downward arrows into first portion 352 in FIG. 3C) due to a concentration gradient of solubility-changing agent 344 between agent-containing layer 338 and first portion 352 of photoresist layer 309. In other words, during pre-exposure bake 350, solubility-changing agent 344 in agent-containing layer 338 drives toward areas of lower concentration of solubility-changing agent 344, such as first portion 352 of photoresist layer 309.

In certain embodiments, one or more properties of agent-containing layer 338 may be selected to achieve a desired level of diffusion of solubility-changing agent 344 (e.g., acid) into certain portions of photoresist layer 309 (e.g., into first portion 352), so that when solubility-changing agent 344 is exposed to a suitable trigger (e.g., a suitable amount of heat), a desired amount of photoresist layer 309 becomes soluble for subsequent development. The desired level of diffusion could be, for example, a target depth of diffusion into photoresist layer 309 to ultimately cause a thinning, or reduction in height, of photoresist layer 309 by the amount of the target depth. The one or more properties of agent-containing layer 338 may include the materials of agent-containing layer 338 (e.g., including a polymer and an agent or agent-generating ingredient), a concentration of solubility-changing agent 344 (e.g., acid) in agent-containing layer 338, a thickness of agent-containing layer 338, and/or other suitable parameters. Additionally, to the extent temperature and/or bake time associated with pre-exposure bake 350 are tailored to affect the depth of diffusion of solubility-changing agent 344 into photoresist layer 309, it may be appropriate to consider how the temperature and time may affect second portion 354 of photoresist layer 309 to avoid or minimize changes to first portion 352 that might negatively impact performance of subsequent exposure and development for patterning second portion 354.

In certain embodiments, at this stage, while solubility-changing agent 344 has diffused into first portion 352 of photoresist layer 309, both first portion 352 and second portion 354 of photoresist layer 309 may remain insoluble for development, as, assuming an appropriate temperature is used for pre-exposure bake 350, solubility-changing agent 344 has not yet reacted with first portion 352 to cause first portion 352 to become soluble for development. In certain embodiments, postponing until after exposure (as described below for FIGS. 3E-3F) modification of first portion 352 to be soluble in a developer may help promote a same or similar volume of photoresist layer 309 interacting with the impinging radiation (actinic radiation 328, described below for FIG. 3E), which may facilitate desirable imaging performance as designed and tuned by a manufacturer of the material of photoresist layer 309. Of course, this disclosure contemplates other approaches.

Second portion 354 may have a reduced thickness relative to a thickness of photoresist layer 309 at earlier stages of process 302. For example, a height (H₂) of second portion 354 may be less than a height (H₁) of photoresist layer 309 as deposited at the stage illustrated in FIG. 3A. The difference between H₁ and H₂ may be the depth (D) that solubility-changing agent 344 penetrated into photoresist layer 309 to cause the solubility change in first portion 352 of photoresist layer 309. The depth of diffusion of solubility-changing agent 344 into first portion 352 may be deliberately designed and controlled to achieve a desired thickness reduction/height (H₂). Thus, the use of agent-containing layer 338 may allow a high degree of control of a height reduction of photoresist layer 309, and ultimately to patterned structures (e.g., analogous to patterned structures 108) formed from photoresist layer 309.

In certain embodiments, a process designer may attempt to achieve a desired level of diffusion and associated solubility change, and thereby associated height reduction of photoresist layer 309 such that sufficient mask budget for pattern transfer exists in the patterned structures being formed. In certain embodiments, the height reduction achieves an aspect ratio (structure height to recess width) of 5:1 or less, such as 2:1. It should be understood, however, that this disclosure contemplates reducing heights of photoresist layer 309 by any suitable amount.

In certain embodiments, the temperature for pre-exposure bake 350 is selected to be high enough to promote diffusion of solubility-changing agent 344 to a desired depth within photoresist layer 309 such that first portion 352 has a desired depth and second portion 354 has a desired height/thickness, while also not being so high as to cause solubility-changing agent 344 to deprotect first portion 352 (and thereby modifying first portion 352 to be soluble for development). In applicable embodiments (e.g., when agent-generating ingredient in agent-containing layer 338 is a TAG), the temperature for pre-exposure bake 350 also may be sufficiently high to cause an agent-generating ingredient in agent-containing layer 338 to generate solubility-changing agent 344.

In certain embodiments, pre-exposure bake 350 may be performed by heating semiconductor workpiece 300 in a process chamber at a temperature between 50° C. to 250° C., for example between 60° C. to 100° C. in certain embodiments, in vacuum or under a gas flow. In a particular example, semiconductor workpiece 300 is baked for 1 to 3 minutes. In certain embodiments, the temperature for pre-exposure bake 350 may be less than a temperature that triggers modification of solubility of first portion 352 by solubility-changing agent 344. For example, the temperature for pre-exposure bake 350 may be approximately 20° C. less than a temperature that triggers modification of solubility of first portion 352 by solubility-changing agent 344. In a particular example, with a moderately diffuse solubility-changing agent 344 (e.g., a moderately diffuse acid), a temperature of 60° C. for pre-exposure bake 350 may be used when deprotection of first portion 352 occurs at temperatures of 80° C. and higher. This disclosure contemplates executing pre-exposure bake 350 in any suitable manner.

As illustrated in FIG. 3D, agent-containing layer 338 may be removed from semiconductor workpiece 300. For example, a solvent wash 356 may be performed to remove agent-containing layer 338, with the solvent being selective to removing agent-containing layer 338. This disclosure contemplates removing agent-containing layer 338 from semiconductor workpiece 300 in any suitable manner. In certain embodiments, removing agent-containing layer 338 prior to a subsequent exposure step for patterning photoresist layer 309 (and particularly exposing second portion 354 of photoresist layer 309) may reduce or eliminate any impact that agent-containing layer 338 might have on patterning performance.

In certain embodiments, solvent wash 356 may be performed using a solvent of 4-methyl-2-pentanol or diisoamyl ether to selectively remove agent-containing layer 338. Although this disclosure describes particular solvents for solvent wash 356, this disclosure contemplates using any suitable solvent for solvent wash 356.

As illustrated in FIG. 3E, in an exposure phase, second portion 354 of photoresist layer 309 is exposed, through first portion 352, to a pattern of actinic radiation 328 (is irradiated) to form a pattern in second portion 354. For example, actinic radiation 328 may be directed toward semiconductor workpiece 300, and particularly to a surface of photoresist layer 309, through a patterned mask 330 to cause a target pattern to form in second portion 354. The target pattern may include exposed regions 332 and non-exposed regions 334 in second portion 354, the characteristics of which may depend on whether a positive or negative photoresist layer 309 is used, as described above.

In embodiments such as the one illustrated in FIGS. 3A-3G, first portion 352, into which solubility-changing agent 344 previously has diffused, is present over second portion 354 prior to exposing semiconductor workpiece 300 (e.g., including second portion 354) to a pattern of actinic radiation 328 for patterning second portion 354 such that first portion 352 is present over second portion 354 during that exposure. In such a scenario, it may be appropriate for the material of first portion 352 to be relatively transparent to the actinic radiation 328 associated with the lithography technology being used to pattern second portion 354, so that second portion 354 can be patterned, as desired. In certain embodiments, first portion 352 being relatively transparent to actinic radiation 328 includes first portion 352 being sufficiently transparent to actinic radiation 328 such that suitable regions of second portion 354 (e.g., exposed regions 332) may be exposed to actinic radiation 328 through first portion 352 (e.g., according to a pattern defined by pattern mask 330).

In certain embodiments, it may be appropriate to increase a dosage of radiation by an appropriate amount (e.g., relative to an example in which exposure is prior to depositing agent-containing layer 338 and/or converting a portion of photoresist layer 309 to be soluble for development) during exposure to promote exposure of suitable regions of second portion 354 (e.g., exposed regions 332) to actinic radiation 328 through first portion 352, possibly depending on a transparency of first portion 352 relative to actinic radiation 328 and while attempting to minimize any negative impact on the intended patterning of second portion 354.

Photoresist layer 309 may include an agent-generating ingredient that is configured to generate a solubility-changing agent in response to a suitable energy (e.g., actinic radiation 328). For example, the agent-generating ingredient in photoresist layer 309 may be a PAG. In response to exposure to actinic radiation 328, the agent-generating ingredient (e.g., the PAG) in exposed regions 332 may generate a solubility-changing agent 336 (e.g., acid) in exposed regions 332.

As illustrated in FIG. 3F, a PEB 340 may be performed to modify to modify portions of photoresist layer 309 to be soluble for development. In particular, PEB 340 may modify first portions 352 of photoresist layer 309 and exposed regions 332 of second portion 354 to be soluble for development, and may leave non-exposed regions 334 of second portion 354 of photoresist layer 309 insoluble for development. For example, PEB 340 may modify first portions 352 of photoresist layer 309 and exposed regions 332 of second portion 354 to be soluble in one or more developers for removing those portions of photoresist layer 309 from semiconductor workpiece 300, and may leave second portion 354 of photoresist layer 309 insoluble for development.

PEB 340 and the associated reaction in exposed regions 332 of second portion 354 may be similar to PEB 240 and the associated reaction in exposed regions 232 described above in connection with FIG. 2D, the description of which is incorporated by reference. A temperature and other conditions for PEB 340 may be tailored such that PEB 340 modifies first portions 352 of photoresist layer 309 and exposed regions 332 of second portion 354 to be soluble for development, and leaves non-exposed regions 334 of second portion 354 of photoresist layer 309 insoluble for development.

At this stage, second portion 354 of photoresist layer 309 may remain insoluble for development. Second portion 354 may have a reduced thickness relative to a thickness of photoresist layer 309 at earlier stages of process 302. For example, a height (H₂) of second portion 354 may be less than a height (H₁) of photoresist layer 309 as deposited at the stage illustrated in FIG. 3A. The difference between H₁ and H₂ may be the depth (D) that solubility-changing agent 344 penetrated into photoresist layer 309 to cause the solubility change in first portion 352 of photoresist layer 309. The depth of diffusion of solubility-changing agent 344 into first portion 352 may be deliberately designed and controlled to achieve a desired thickness reduction/height (H₂). Thus, the use of agent-containing layer 338 may allow a high degree of control of a height reduction of photoresist layer 309, and ultimately to patterned structures (e.g., analogous to patterned structures 108) formed from photoresist layer 309.

As illustrated in FIG. 3G, in a developing phase, photoresist layer 309 may be developed using a suitable development process to remove soluble portions of photoresist layer 309. During the developing phase, and according to the illustrated example of a positive photolithography process, soluble portions of photoresist layer 309 may be removed using a suitable dry etch or wet etch process, and thereby forming photoresist layer 309 into a mask according to pattern mask 330 that can then be used to perform further fabrication process, such as may be associated with patterning process 102 of FIGS. 1A-1F.

The soluble portions of photoresist layer 309 that are removed during the development phase may include first portion 352 of photoresist layer 309 and exposed regions 332 of second portion 354 of photoresist layer 309. Following removal of soluble portions of photoresist layer 309, non-exposed regions 334 of second portion 354 of photoresist layer 309 remain and form patterned structures 308. Additionally, removal of soluble portions of photoresist layer 309 forms recesses 310 in photoresist layer 309. Recesses 310 in photoresist layer 309 may be used in an etching process (e.g., patterning process 102 of FIGS. 1A-1F) to etch features in intermediate layer 306. Recesses 310 may have a lateral width (W). Recesses 310 may have the same or different widths in any suitable combination.

Patterned structures 308 have a reduced height H₂ relative to an initial height H₁ of photoresist layer 309. The height reduction (H₁-H₂) may corresponding to a depth D of first portion 352 of photoresist layer 309, which is removed as part of the development process. This height reduction, which also may be referred to as a thickness reduction, may reduce an aspect ratio (height of patterned structure 308:width of adjacent recess 310) in semiconductor workpiece 300. This reduction in aspect ratio may persist (although not necessarily by a same amount) as the pattern formed by patterned structures 308 is used as part of a patterning process to pattern underlying layers. For example, using semiconductor workpiece 300 at the state illustrated in FIG. 3G as semiconductor workpiece 100 at the stage illustrated in FIG. 1A in connection with the anti-spacer patterning process 102 illustrated in FIGS. 1A-1F (and subsequent pattern transfer illustrated in FIG. 1G), the reduction in aspect ratio associated with the pattern defined by patterned structures 308 may result in a reduction in aspect ratio at a later stage of process 102 (e.g., at the stage illustrated in FIG. 1F).

The developing phase of FIG. 3G may be similar to the developing phase of FIG. 2E, the details of which are incorporated by reference.

As an example variation on patterning process 302, during the stage illustrated in FIG. 3C, in addition to causing solubility-changing agent 344 to diffuse into portions (e.g., first portion 352) of photoresist layer 309, pre-exposure bake 350 also may modify those portions (e.g., first portion 352) of photoresist layer 309 to be soluble for development. In particular, pre-exposure bake 350 may modify portions of photoresist layer 309 to be soluble in one or more developers for removing those portions of photoresist layer 309 from semiconductor workpiece 300. For example, pre-exposure bake 350 may modify first portions 352 of photoresist layer 309 to be soluble for development and leave second portion 354 of photoresist layer 309 insoluble for development.

For example, pre-exposure bake 350 may cause solubility-changing agent 344 to diffuse from agent-containing layer 338 to first portion 352 of photoresist layer 309. The heat associated with pre-exposure bake 350 may cause solubility-changing agent 344 to react with other substances (e.g., a polymer) of first portion 352 to cause first portion 352 to become soluble for development. For example, in a similar type of deprotection reaction to that described above, pre-exposure bake 350 may cause solubility-changing agent 344 to convert one or more of the pendant groups of another substance (e.g., a polymer) of first portion 352 of photoresist layer 309 to cause first portion 352 to become soluble for development in a given developer.

In certain embodiments, to accomplish both the diffusion of solubility-changing agent 344 from agent-containing layer 338 to first portion 352 of photoresist layer 309 and the modification of those portions (e.g., first portion 352) of photoresist layer 309 to be soluble for development, pre-exposure bake 350 may be performed at a higher temperature that the above-described temperature for pre-exposure bake 350. In certain embodiments, the temperature of pre-exposure bake 350 may be approximately 20° C. higher than the above-described temperature of pre-exposure bake 350. For example, in this variation, pre-exposure bake 350 may be performed by heating semiconductor workpiece 300 in a process chamber at a temperature between 50° C. to 250° C., for example between 80° C. to 160° C. in certain embodiments, in vacuum or under a gas flow. In a particular example, semiconductor workpiece 300 is baked for 1 to 3 minutes. The pre-exposure bake conditions may be selected to promote a degree of crosslinking in the exposed resist for improved contrast and reduced LER. This disclosure contemplates executing pre-exposure bake 350 in any suitable manner.

In certain embodiments, agent-containing layer 338 includes an agent-generating ingredient that generates solubility-changing agent 344 in response to a suitable activation trigger (e.g., heat or radiation). For example, in an implementation in which solubility-changing agent 344 is an acid, the agent-generating ingredient may include a TAG or a PAG, which may be included in agent-containing layer 338 as deposited. In the case of a TAG, pre-exposure bake 350 or a separate heating step may be performed to cause the generation of solubility-changing agent 344. In the case of a PAG, a separate irradiation step may be performed prior to pre-exposure bake 350 to generate solubility-changing agent 344.

In certain embodiments, the solubility modification of first portion 352 of photoresist layer 309 may occur occurs when a pendant group of the polymer (of photoresist layer 309) changes solubility. In some cases, the total volume of this changed group that is sufficient to modify the solubility of first portion 352 for subsequent removal may be below 50% (and potentially well below 50%) of that available in first portion 352. Post-exposure (e.g., after FIG. 3E), the PAG present in first portion 352 of photoresist layer 309 may decompose and react with the remaining protected pendant groups. In some scenarios, the deprotection reaction associated with solubility-changing agent 344 within first portion 352 may have consumed a majority of this pendant deprotectable group, and any acid resulting from exposure of the PAG in first portion 352 (e.g., in FIG. 3E) may diffuse farther within the bake time (e.g., of PEB 340) but remain as reactive. Even in this example in which first portion 352 of photoresist layer 309 is deprotected (modified to be soluble) prior to exposure (in FIG. 3E), then the transparency of first portion 352 to the impinging photons associated with actinic radiation 328 may be preserved as these groups may constitute a low percentage of the overall volume of first portion 352.

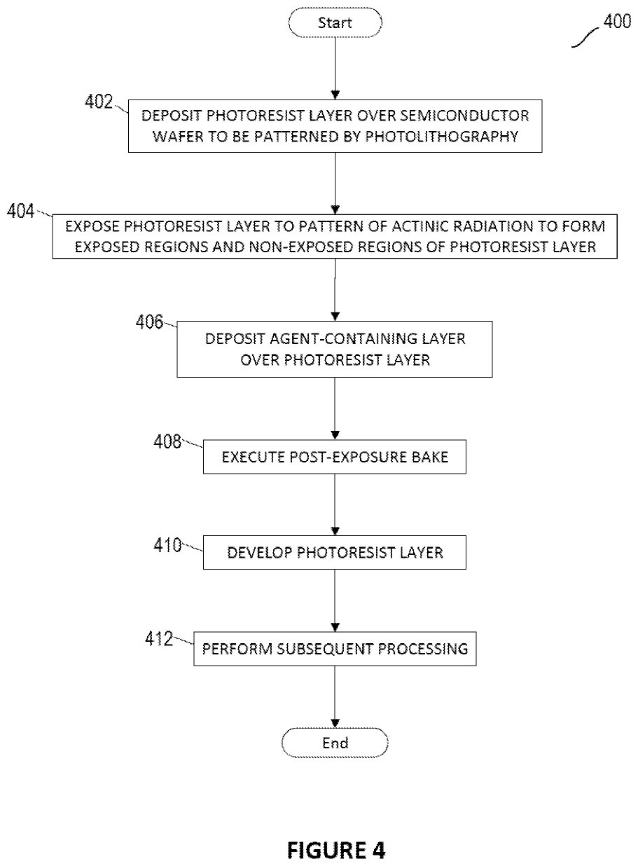

FIG. 4 illustrates an example method 400 for patterning a semiconductor workpiece, according to certain embodiments. Method 400 may be analogous to portions or all of patterning process 202, and for purposes of describing example method 400, reference is made primarily to reference numerals used in connection with FIGS. 2A-2E. Furthermore, aspects of at least FIGS. 2A-2E not described in connection with FIG. 4 are incorporated by reference. Method 400, however, may implement any suitable patterning process.

At step 402, photoresist layer 209 may be deposited over a semiconductor wafer (semiconductor workpiece 200) to be patterned by photolithography. Photoresist layer 209 has a first height (H₁). At step 404, photoresist layer 209 is exposed to a pattern of actinic radiation 228 to form exposed regions 232 and non-exposed regions 234 of photoresist layer 209. In certain embodiments, a lithography technology for exposing photoresist layer 209 to the pattern of actinic radiation 228 includes one or more of immersion lithography technique or i-line lithography. This disclosure contemplates using any suitable type of lithography technology.

At step 406, agent-containing layer 238 is deposited over photoresist layer 209. In certain embodiments, depositing agent-containing layer 238 over photoresist layer 209 includes depositing an agent-containing material by spin-coating (e.g., using spin-on deposition technique 214) the agent-containing material over photoresist layer 209. The semiconductor wafer (semiconductor workpiece 200) may include top coat 226 formed over photoresist layer 209 prior to depositing agent-containing layer 238, top coat 226 being between photoresist layer 209 and agent-containing layer 238. Top coat 226 may be configured to act as a diffusion barrier.

At step 408, a PEB 240 of semiconductor wafer (semiconductor workpiece 200) is executed. PEB 240 may modify portions of photoresist layer 209 to form soluble portions of photoresist layer 209 for development. The soluble portions of photoresist layer 209 may include exposed regions 232 and top portions 242 of non-exposed regions 234.

In certain embodiments, to modify the portions of photoresist layer 209 to form the soluble portions of photoresist layer 209 for development, PEB 240 causes solubility-changing agent 244 to diffuse from agent-containing layer 238 to top portions 242 of non-exposed regions 234. Solubility-changing agent 244 causes top portions 242 of non-exposed regions 234 to become soluble for development. PEB 240 may cause solubility-changing agent 244 to diffuse from agent-containing layer 238 to top portions 242 of non-exposed regions 234 up to a target depth (D). The target depth (D) may correspond to a difference between the first height (H₁) of photoresist layer 209 and the second height (H₂) of bottom portions 248 of photoresist layer 209. In certain embodiments, one or more of a type of solubility-changing agent 244, a concentration of solubility-changing agent 244, and a thickness of agent-containing layer 238 may be selected such that PEB 240 causes solubility-changing agent 244 to diffuse from agent-containing layer 238 to top portions 242 of non-exposed regions 234 of photoresist layer 209 by the target depth.

Additionally, in certain embodiments, to modify the portions of photoresist layer 209 to form the soluble portions of photoresist layer 209 for development, PEB 240 causes solubility-changing agent 236 activated by actinic radiation 228 in exposed regions 232 to cause exposed regions 232 to become soluble for development. In certain embodiments, prior to PEB 240, exposed regions 232 include solubility-changing agent 236, solubility-changing agent 236 having been generated in response to actinic radiation 228. In certain embodiments, solubility-changing agent 236 and solubility-changing agent 244 include acid, and photoresist layer 209 includes an acid-reactive material.

In certain embodiments, agent-containing layer 238, as deposited, includes a polymer and solubility-changing agent 244 (e.g., a free acid) or an agent-generating ingredient (e.g., a TAG or PAG) for generating solubility-changing agent 244 (e.g., acid).

At step 410, photoresist layer 209 may be developed to remove selectively the soluble portions of photoresist layer 209. Remaining portions (e.g., bottom portions 248) of non-exposed regions 234 of photoresist layer 209 may form patterned structures 208 of the semiconductor wafer (semiconductor workpiece 200) and have a second height (H₂) that is less than the first height (H₁) of photoresist layer 209.

At step 412, subsequent processing may be performed. For example, patterned structures 208 of the semiconductor wafer (semiconductor workpiece 200) having the second height (H₂) may be used to form sub-resolution features in an underlying layer (e.g., intermediate layer 206) of the semiconductor wafer (semiconductor workpiece 200).

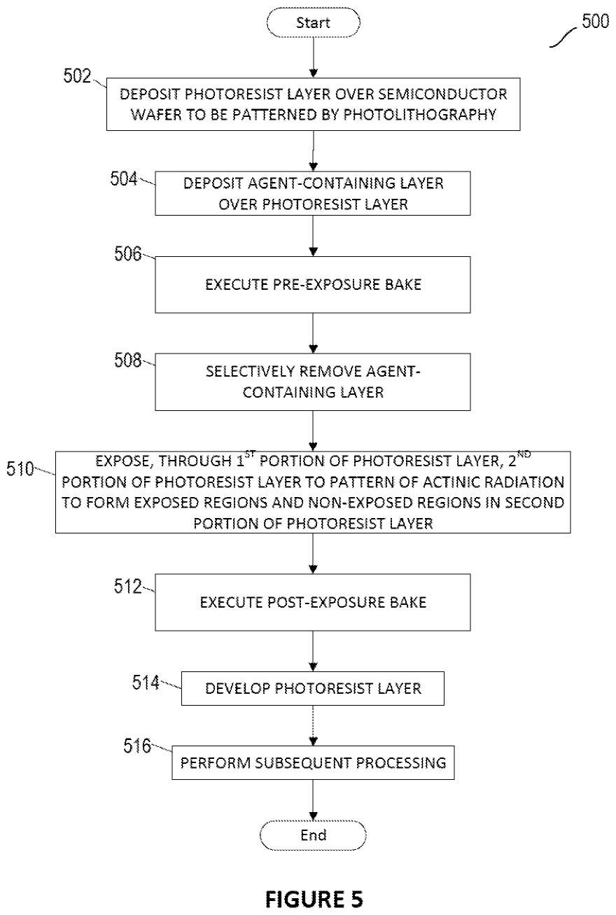

FIG. 5 illustrates an example method 500 for patterning a semiconductor workpiece, according to certain embodiments. Method 500 may be analogous to portions or all of patterning process 302, and for purposes of describing example method 500, reference is made primarily to reference numerals used in connection with FIGS. 3A-3G. Furthermore, aspects of at least FIGS. 3A-3G not described in connection with FIG. 5 are incorporated by reference. Method 500, however, may implement any suitable patterning process.

At step 502, photoresist layer 309 may be deposited over a semiconductor wafer (semiconductor workpiece 300) to be patterned by photolithography. Photoresist layer 309 has a first height (H₁).

At step 504, agent-containing layer 338 is deposited over photoresist layer 209. In certain embodiments, depositing agent-containing layer 338 over photoresist layer 309 includes depositing an agent-containing material by spin-coating (e.g., using spin-on deposition technique 314) the agent-containing material over photoresist layer 309. Semiconductor wafer (semiconductor workpiece 300) may include top coat 326 formed over photoresist layer 309 prior to depositing agent-containing layer 338, top coat 326 being between photoresist layer 309 and agent-containing layer 338. Top coat 326 may be configured to act as a diffusion barrier.

At step 506, a pre-exposure bake 350 of the semiconductor wafer (semiconductor workpiece 300) is executed. Pre-exposure bake 350 may cause a first solubility-changing agent 344 to diffuse from agent-containing layer 338 to a first portion 352 of photoresist layer 309. First portion 352 may be disposed between agent-containing layer 338 and a second portion 354 of photoresist layer 309. For example, first portion 352 and second portion 354 may be a top portion and a bottom portion, respectively, of photoresist layer 309.

In certain embodiments, pre-exposure bake 350 may modify first portion 352 of photoresist layer 309 to be soluble for development. In certain embodiments, to modify first portion 352 to be soluble for development, pre-exposure bake 350 may cause a solubility-changing agent 344 to diffuse from agent-containing layer 338 to first portion 352 of photoresist layer 309. In addition, pre-exposure bake 350 may cause the diffused solubility-changing agent 344 to react with a material (e.g., a polymer) of first portion 352 to cause first portion 352 of photoresist layer 309 to become soluble for development.

In certain other embodiments, while pre-exposure bake 350 causes solubility-changing agent 344 to diffuse into photoresist layer 309 a target distance (e.g., first portion 352 of photoresist layer 309), pre-exposure bake 350 is executed at a sufficiently low temperature so as not to cause the diffused solubility-changing agent 344 to react with a material (e.g., a polymer) of first portion 352 to cause first portion 352 of photoresist layer 309 to become soluble for development. In such embodiments, a later trigger (e.g., PEB 340 at step 512) may cause the diffused solubility-changing agent 344 to react with a material (e.g., a polymer) of first portion 352 to cause first portion 352 of photoresist layer 309 to become soluble for development.

The pre-exposure bake 350 may cause solubility-changing agent 344 to diffuse from agent-containing layer 338 to first portion 352 up to a target depth (D). The target depth (D) may correspond to a difference between the first height (H₁) of photoresist layer 309 and the second height (H₂) of second portion 354. In certain embodiments, one or more of a type of solubility-changing agent 344, a concentration of solubility-changing agent 344, and a thickness of agent-containing layer 338 may be selected such that pre-exposure bake 350 causes solubility-changing agent 344 to diffuse from agent-containing layer 338 to first portion 352 by the target depth.

In certain embodiments, agent-containing layer 338, as deposited, includes a polymer and solubility-changing agent 344 (e.g., a free acid) or an agent-generating ingredient (e.g., a TAG or PAG) for generating solubility-changing agent 344 (e.g., acid).

At step 508, agent-containing layer 338 may be selectively removed from the semiconductor wafer (semiconductor workpiece 300). For example, agent-containing layer 338 may be selectively removed from a surface of photoresist layer 309 (or top coat 326, if present).

At step 510, second portion 354 of photoresist layer 309 may be exposed, through first portion 352, to a pattern of actinic radiation 328 to form exposed regions 332 and non-exposed regions 334 in second portion 354. In certain embodiments, a lithography technology for exposing second portion 354 to the pattern of actinic radiation 328 includes one or more of immersion lithography technique or i-line lithography. This disclosure contemplates using any suitable type of lithography technology. First portion 352 may be relatively transparent to a wavelength of the actinic radiation 328 of the pattern of actinic radiation 328.

At step 512, a PEB 340 of the semiconductor wafer (semiconductor workpiece 300) may be performed. PEB 340 may modify exposed regions 332 of second portion 354 to be soluble for development. In certain embodiments, to modify exposed regions 332 of second portion 354 to be soluble for development, PEB 340 causes a solubility-changing agent 336 activated by the actinic radiation 328 in exposed regions 332 of second portion 354 to react with a material (e.g., a polymer) of exposed regions 332 of second portion 354 to cause exposed regions 332 of second portion 354 to become soluble for development. In certain embodiments, prior to PEB 340, exposed regions 332 of second portion 354 include solubility-changing agent 336, solubility-changing agent 336 having been generated in response to actinic radiation 328.

In certain embodiments, as described above with reference to step 506, PEB 340 may cause solubility-changing agent 344 diffused into first portion 352 of photoresist layer 309 to cause first portion 352 of photoresist layer 309 to become soluble for development. For example, PEB 340 may cause solubility-changing agent 344 diffused into first portion 352 of photoresist layer 309 at step 506 to react with a material (e.g., a polymer) of first portion 352 of photoresist layer 309 to cause first portion 352 to become soluble for development.

In certain embodiments, solubility-changing agent 336 and solubility-changing agent 344 include acid, and photoresist layer 309 includes an acid-reactive material.

At step 514, photoresist layer 309 may be developed to remove selectively first portion 352 and exposed regions 332 of second portion 354, as modified by PEB 340 at step 512. Remaining portions of non-exposed regions 334 of second portion 354 may form patterned structures 308 of the semiconductor wafer (semiconductor workpiece) and have a second height (H₂) that is less than the first height (H₁) of photoresist layer 309.

At step 516, subsequent processing may be performed. For example, patterned structures 308 of the semiconductor wafer (semiconductor workpiece 300) having the second height (H₂) may be used to form sub-resolution features in an underlying layer (e.g., intermediate layer 306) of the semiconductor wafer (semiconductor workpiece 300).

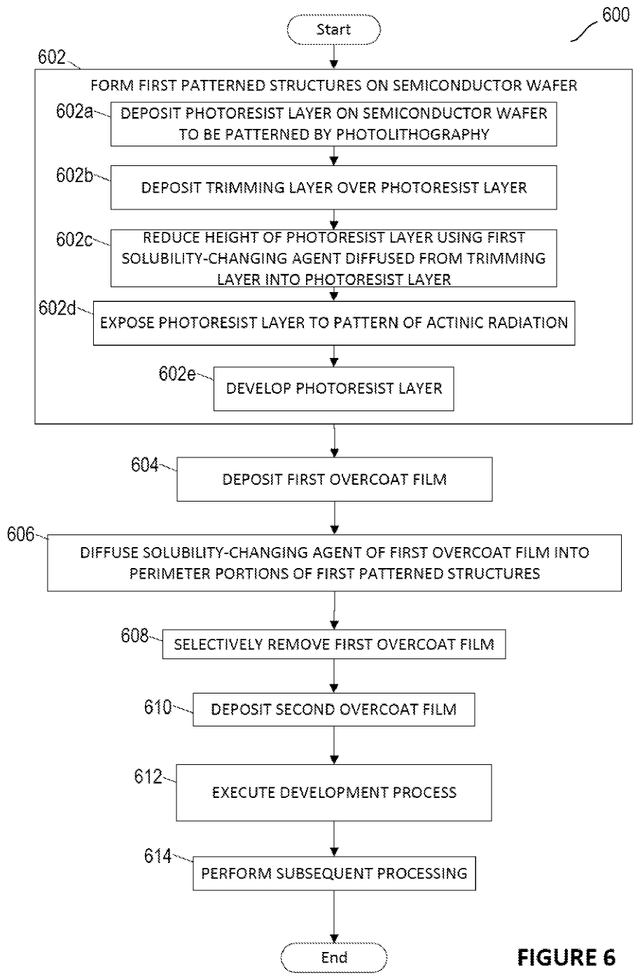

FIG. 6 illustrates an example method 600 for patterning a semiconductor workpiece, according to certain embodiments. Method 600 may be analogous to portions or all of patterning process 102, and for purposes of describing example method 600, reference is made primarily to reference numerals used in connection with FIGS. 1A-1G. Furthermore, aspects of at least FIGS. 1A-1G not described in connection with FIG. 6 are incorporated by reference. Method 600, however, may implement any suitable patterning process. Method 600 also may incorporate aspects of patterning processes 202 and 302, and methods 400 and 500.

At step 602, patterned structures 108 may be formed on a semiconductor wafer (e.g., semiconductor workpiece 100). Patterned structures 108 may define recesses 110 and have a height (H₂). For example, semiconductor workpiece 100 at this stage of method 600 may correspond to semiconductor workpiece 200 at the stage illustrated in FIG. 2E, having been formed according to patterning process 202. In such an example, structures 108 may correspond to structures 208, and recesses 110 may correspond to recesses 210. As another example, semiconductor workpiece 100 at this stage of method 600 may correspond to semiconductor workpiece 300 at the stage illustrated in FIG. 3G, having been formed according to patterning process 302. In such an example, structures 108 may correspond to patterned structures 308, and recesses 110 may correspond to recesses 310.

Whether formed according to patterning process 202, patterning process 302, or otherwise, forming patterned structures 108 may include steps 602a-602e. At step 602a, a photoresist layer (e.g., photoresist layer 209/309) may be deposited on a semiconductor wafer (semiconductor workpiece 100) to be patterned by photolithography. The photoresist layer has a height (H₁) that is greater than the height (H₂) of patterned structures 108. At step 602b, a trimming layer (e.g., agent-containing layer 238/338) may be deposited over the photoresist layer (e.g., photoresist layer 209/309) for subsequently trimming a height/thickness of the photoresist layer.

At step 602c, prior to developing the photoresist layer, the height (H₁) of the photoresist layer may be reduced to the height (H₂) using a first solubility-changing agent (e.g., solubility-changing agent 244/344) diffused from the trimming layer (e.g., agent-containing layer 238/338) into the photoresist layer (e.g., into top portions 242 of non-exposed regions 234 subsequent to exposing photoresist layer 209 to actinic radiation 228 to pattern photoresist layer 209, or into first portion 352 prior to exposing photoresist layer 309 to actinic radiation 328 to pattern photoresist layer 309). Solubility-changing agent 244/344 may include acid.

At step 602d, the photoresist layer may be exposed to a pattern of actinic radiation. As described above, the photoresist layer may be exposed to the pattern actinic radiation prior to step 602c (e.g., in patterning process 202) or subsequent to step 602c (e.g., in patterning process 302). At step 602e, the photoresist layer may be developed, and remaining portions of the photoresist layer may form microfabricated structures (e.g., patterned structures 108) defining recesses (e.g., recesses 110).

With the semiconductor wafer (semiconductor workpiece 100) having been formed at the stage illustrated in FIG. 1A, at step 604, overcoat film 112 may be deposited on the semiconductor wafer. Overcoat film 112 may fill recesses 110 and cover patterned structures 108. At step 606, a solubility-changing agent 117 (e.g., acid) of overcoat film 112 may be diffused into perimeter portions of patterned structures 108, forming modified portions 118. At step 606, overcoat film 112 may be selectively removed. At step 608, overcoat film 120 may be deposited on the semiconductor wafer (semiconductor workpiece 100). Overcoat film 120 may fill recesses 110 and cover patterned structures 108.

At step 610, a development process may be executed using one or more suitable developers. The development process may remove a first portion of overcoat film 120 to reveal at least a portion of the perimeter portions (modified portions 118) of patterned structures 108 and removes the perimeter portions (modified portions 118) of patterned structures 108 to define patterned structures 123. Patterned structures 123 may include remaining portions of patterned structures 108 (unmodified portions 119) and remaining portions 122 of overcoat film 120 interspersed between the remaining portions (unmodified portions 119) of patterned structures 108. Patterned structures 123 may define recesses 124, which may have a smaller width than recesses 110, and thereby define a narrow critical dimension that can be transferred to underlying layers. In certain embodiments, recesses 124 have a width of 10 nanometers or less.

Methods 400, 500, and 600 may be combined with each other or other methods and performed using the systems and apparatuses described herein. Although shown in a logical order, the arrangement and numbering of the steps of methods 400, 500, and 600 are not intended to be limited. The steps of methods 400, 500, and 600 may be performed in any suitable order or concurrently with one another as may be apparent to a person of skill in the art.

FIGS. 7-9 illustrate example processing tools that may be used, along or in combination, to implement certain embodiments of this disclosure.

FIG. 7 illustrates a block diagram of an example lithography system 700, according to certain embodiments. Lithography system 700 is just one example of a lithography system that may be used with certain embodiments. In the illustrated example, lithography system 700 includes a track system 702 and a projection scanner 704. In certain embodiments, lithography system 700 is generally configured for performing patterning process 202.

Scanner 704 may be configured to perform an exposure phase of a photolithography process. In certain embodiments, scanner 704 is a combination of an optical and mechanical system to scan an optical image of a pattern printed on a photomask (e.g., pattern mask 230,330) onto the surface of a wafer (e.g., semiconductor workpiece 100,200,300) coated with resist (e.g., photoresist layer 209, 309). After scanning the pattern once, scanner 704 may be operated to step to an adjacent location on the same wafer where the scan is repeated to form another copy of the pattern. In this manner, the photoresist layer is exposed to multiple copies of the pattern arranged in a rectangular matrix on the surface of the wafer.

Track system 702 includes a series of process modules assembled to allow potentially sequential execution of processes for the lithography process prior to the exposure and after the exposure step performed by scanner 704. Track system 702 provides the material processes such as coating the wafer with photoresist, baking the photoresist, and developing the photoresist after exposure. In the illustrated example, the process modules of track system 702 include a spin-coating module 1206, a spin-coating module 710, a PEB module 712, and a developing module 714 for developing the exposed photoresist. Spin-coating modules 706 and 710 include a spin-coater, an example of which is described below with reference to FIG. 9. Photoresist materials, agent-containing layer materials, overcoat materials, and solvents are connected from a liquid supply system to suitable processing modules (e.g., spin-coating modules 706 and 710, developing module 714, etc.) via pipelines, filters, valves, and pumps.

In addition to process modules, track system 702 includes an imaging module 708 and could also include an inspection and metrology (IM) module.

Imaging module 708 may be an optical imaging module used to identify defects prior to exposing the resist to a radiation pattern in scanner 704. Wafers coated with photoresist are received from spin-coating module 706 and imaged in imaging module 708 using an imaging system that includes light sources and cameras. The light sources are configured to illuminate the wafer, while the cameras create photographic images of the surfaces. In certain embodiments, the imaging system of imaging module 708 includes cameras to image the wafer from various directions (e.g., from the top (side coated with photoresist), bottom (backside), and side (beveled edges)). The cameras may be coupled to a controller of the imaging system that acquires and transmits the images to an inspection device for image analysis. The inspection device may identify defects using, for example, a processor of the inspection device configured to execute instructions stored in an electronic memory of the inspection device to perform appropriate image analysis. A defective wafer may be reworked or scrapped, as appropriate.

An IM module may receive wafers after a photoresist layer has been exposed to a pattern of actinic radiation in scanner 704, and the pattern has been transferred to the photoresist in developing module 714, where the exposed photoresist is developed to form a patterned photoresist layer. The quality of the photoresist pattern is evaluated by inspecting and measuring various images of the photoresist pattern in the IM module. The IM module may include, for example, a scanning electron microscope (SEM) for measuring critical dimensions in the photoresist pattern. Wafers may fail inspection because of patterning defects or if the measurements are not within specified limits. Failed wafers may be discarded, or, if possible, reworked by stripping the photoresist and repeating the photoresist patterning process.

Lithography system 700 may include a transfer system to move a wafer (e.g., a semiconductor workpiece) from module-to-module of track system 702, as well as from track system 702 to projection scanner 704 (which may be considered “off track”) and from projection scanner 704 back to track system 702.

FIG. 8 illustrates a block diagram of an example lithography system 800, according to certain embodiments. Lithography system 800 is just one example of a lithography system that may be used with certain embodiments of this disclosure. In the illustrated example, lithography system 800 includes a track system 802 and a projection scanner 804. In certain embodiments, lithography system 800 is generally configured for performing patterning process 302. In general, lithography system 800 is similar to lithography system 700, except that lithography system 800 has been configured for performing patterning process 302. The description of lithography system 700 is incorporated by reference.

Scanner 804 may be configured to perform an exposure phase of a photolithography process, as described above with reference to scanner 704.

Track system 802 includes a series of process modules assembled to allow potentially sequential execution of processes for the lithography process prior to the exposure and after the exposure step performed by scanner 804. Track system 802 provides the material processes such as coating the wafer with photoresist, baking the photoresist, and developing the photoresist after exposure. In the illustrated example, the process modules of track system 802 include a spin-coating module 806 (e.g., for depositing photoresist layer 309), a spin-coating module 808 (e.g., for depositing agent-containing layer 338), a pre-exposure bake module 810, a solvent-wash module 812, a PEB module 814, and a developing module 816 for developing the exposed photoresist. Spin-coating modules 806 and 808 include a spin-coater, an example of which is described below with reference to FIG. 9. Photoresist materials, agent-containing layer materials, overcoat materials, and solvents are connected from a liquid supply system to suitable processing modules (e.g., spin-coating modules 806 and 808, developing module 816, etc.) via pipelines, filters, valves, and pumps. Although not shown, track system 802 may include an imaging module and an IM module similar to those described above.

Lithography system 800 may include a transfer system to move a wafer (e.g., a semiconductor workpiece) from module-to-module of track system 802, as well as from track system 802 to projection scanner 804 (which may be considered “off track”) and from projection scanner back 804 to track system 802.

FIG. 9 illustrates an example liquid-based spin-on deposition system 900, according to certain embodiments. For example, liquid-based spin-on deposition system 900 may be used to process any of the described semiconductor workpieces to deposit any of the photoresist layers, barrier layers, photoresist formulas, overcoat films or other suitable materials described in this disclosure. In certain embodiments, spin-on deposition system 900 may be a semi-closed spin-on deposition system used for coating substrates (wafers) with a desired layer. The semi-closed configuration may allow fume control and minimize exhaust volume.

In the illustrated example, spin-on deposition system 900 includes a process chamber 902 that includes a substrate holder 904 for supporting, heating, and rotating (spinning) a substrate 906 (which may include any of the semiconductor workpieces described in this disclosure at appropriate stages of processing), a rotating apparatus 908 (e.g., a motor), and a liquid delivery nozzle 910 configured for providing a processing liquid 912 to an upper surface of the substrate 906. Liquid supply systems 914, 916, and 918 supply different processing liquids to the liquid delivery nozzle 910. For depositing a photoresist, the different processing liquids can include, for example, a first reactant in a first liquid, a second reactant in a second liquid, and a rinsing liquid. In certain embodiments, spin-on deposition system 900 includes additional liquid delivery nozzles for providing different liquids to substrate 906. Example rotating speeds can be between about 500 rpm and about 1500 rpm, for example 1000 rpm, during exposure of an upper surface of substrate 906 to processing liquid 912.

Spin-on deposition system 900 may include a controller 920 that can be coupled to and control process chamber 902; liquid supply systems 914, 916, and 918; liquid delivery nozzle 910; rotating apparatus 908, mechanism for heating substrate holder 904. Substrate 906 may be under an inert atmosphere during film deposition. Spin-on deposition system 900 may be configured to process substrates 906 of any suitable size.

Certain embodiments may provide none, some, or all of the following technical advantages. Other advantages may be described throughout this disclosure or otherwise be apparent from this disclosure to one of skill in the art.

Certain embodiments improve feature fidelity even for older lithographic platforms, such as immersion lithography (e.g., 193 nanometer immersion lithography), i-line lithography, or other older lithographic technologies that implement additional processing (e.g., anti-spacer double-patterning lithography) to achieve sub-resolution features. Certain embodiments are able to achieve sub-EUV dimensions using 193 immersion and other older lithographic technologies without performing additional ALD depositions and etches. Relative to other technologies, such as EUV or an alternative spacer-based multi-patterning technique, anti-spacer technology may be a lower cost, track-based approach for achieving sub-EUV dimensions. As certain embodiments of this disclosure improve anti-spacer technology, certain embodiments provide an improved, lower cost, track-based approach for achieving sub-EUV dimensions.

Certain embodiments reduce or eliminate wiggling/collapse in anti-spacer patterns. Certain embodiments improve anisotropic etch transfer critical dimension by reducing shadowing effects from aspect ratio combined with sidewall angle. Certain embodiments promote track-based resolution scaling by providing improved features that can be implemented on-track.

As another example, a technique that includes depositing a photoresist layer at a reduced height to attempt to reduce an aspect ratio for subsequent pattern transfer can lead to problems. When performing an exposure, the photoresist height is optimized to take advantage of the full aerial image and photons to which the photoresist is being exposed. A thinner photoresist of non-optimized height may experience loss in the patterning, including non-optimal profile, surface roughness, and the like. In contrast, certain embodiments preserve the photoresist height to achieve desired patterning, and reduce the height of the resist after exposure, such as by diffusing acid or another agent into the planar resist to cause solubility-changing reactions either pre-exposure or post-exposure. In certain embodiments, a process designer may attempt to achieve a desired level of diffusion and associated solubility change, and thereby associated height reduction of patterned structures such that sufficient mask budget for pattern transfer exists in the patterned structures being formed. In certain embodiments, the height reduction achieves an aspect ratio (structure height to recess width) of 5:1 or less, such as 2:1.

As another example, using the agent-containing layer disclosed herein may reduce a height of a photoresist layer with little to no change to a width (critical dimension) of a feature patterned from the resist layer (e.g., a mandrel). For example, a technique that includes depositing a layer to trim a height of the mandrel feature after development likely would cause the feature size to be reduced both vertically and laterally, undesirably disrupting the targeted width of the feature. In contrast, by applying the agent-containing layer prior to development, certain embodiments are able to selectively trim the photoresist layer in a vertical (e.g., top-down) direction).

Although certain embodiments are described as providing certain advantages for 193 nanometer immersion lithography technology, i-line technology, and other older lithography technologies, including the ability to provide improved sub-EUV critical dimensions, sub-10 nanometer critical dimension, and the like, this disclosure can be implemented using any suitable lithography technology, including EUV technology.

Furthermore, although this disclosure primarily describes embodiments in which the disclosed techniques are used to pattern photoresists and/or layers underlying the photoresists, embodiments of this disclosure may be used to pattern any suitable type of layer. For example, this disclosure may be used to pattern films other than photoresist layers that may benefit from a top-down thinning process.

Example embodiments of this disclosure are summarized here. Other embodiments can also be understood from the entirety of the specification as well as the claims filed herein.

Example 1. A method includes depositing a photoresist layer over a semiconductor wafer to be patterned by photolithography, the photoresist layer having a first height, and exposing the photoresist layer to a pattern of actinic radiation to form exposed regions and non-exposed regions of the photoresist layer. The method further includes depositing an agent-containing layer over the photoresist layer and executing a post-exposure bake of the semiconductor wafer. The post-exposure bake modifies portions of the photoresist layer to form soluble portions of the photoresist layer for development. The soluble portions of the photoresist layer include the exposed regions and top portions of the non-exposed regions. The method further includes developing the photoresist layer to remove selectively the soluble portions, remaining portions of the non-exposed regions forming patterned structures of the semiconductor wafer and having a second height that is less than the first height.

Example 2. The method of Example 1, where to modify the portions of the photoresist layer to form the soluble portions of the photoresist layer for development, the post-exposure bake causes: a first solubility-changing agent to diffuse from the agent-containing layer to the top portions of the non-exposed regions of the photoresist layer, the first solubility-changing agent causing the top portions of the non-exposed regions of the photoresist layer to become soluble for development; and a second solubility-changing agent activated by the actinic radiation in the exposed regions of the photoresist layer to cause the exposed regions of the photoresist layer to become soluble for development.

Example 3. The method of any one of Examples 1-2, where: the post-exposure bake causes the first solubility-changing agent to diffuse from the agent-containing layer to the top portions of the non-exposed regions of the photoresist layer up to a target depth, the target depth corresponding to a difference between the first height and the second height; and one or more of an agent type, an agent concentration, and an agent-containing layer thickness of the agent-containing layer are selected such that the post-exposure bake causes the first solubility-changing agent to diffuse from the agent-containing layer to the top portions of the non-exposed regions of the photoresist layer by the target depth.

Example 4. The method of any one of Examples 1-3, where the first solubility-changing agent and the second solubility-changing agent include acid and the photoresist layer includes an acid-reactive material.

Example 5. The method of any one of Examples 1-4, where the agent-containing layer, as deposited, includes: a polymer; and the first solubility-changing agent or an agent-generating ingredient for generating the first solubility-changing agent.

Example 6. The method of any one of Examples 1-5, where, prior to the post-exposure bake, the exposed portions of the photoresist layer include the second solubility-changing agent, the second solubility-changing agent being generated in response to the actinic radiation.

Example 7. The method of any one of Examples 1-6, where depositing the agent-containing layer over the photoresist layer includes depositing an agent-containing material by spin-coating the agent-containing material over the photoresist layer.

Example 8. The method of any one of Examples 1-7, where the semiconductor wafer further includes a top coat formed over the photoresist layer prior to depositing the agent-containing layer over the photoresist layer, such that the top coat is between the photoresist layer and the agent-containing layer, the top coat being configured to act as a diffusion barrier.

Example 9. The method of any one of Examples 1-8, where a lithography technology for exposing the photoresist layer to the pattern of actinic radiation includes one or more of immersion lithography technique or i-line lithography.

Example 10. The method of any one of Examples 1-9, further including using the patterned structures of the semiconductor wafer having the second height to form sub-resolution features in an underlying layer of the semiconductor wafer.

Example 11. A method includes depositing a photoresist layer on a semiconductor wafer to be patterned by photolithography, the photoresist layer having a first height. The method further includes depositing an agent-containing layer over the photoresist layer and executing a pre-exposure bake of the semiconductor wafer. The pre-exposure bake causes a first solubility-changing agent to diffuse from the agent-containing layer to a first portion of the photoresist layer, the first portion of the photoresist layer being disposed between the agent-containing layer and a second portion of the photoresist layer. The method further includes selectively removing the agent-containing layer and exposing, through the first portion of the photoresist layer, the second portion of the photoresist layer to a pattern of actinic radiation to form exposed regions and non-exposed regions in the second portion of the photoresist layer. The method further includes executing a post-exposure bake of the semiconductor wafer, the post exposure bake modifying the exposed regions of the second portion of the photoresist layer to be soluble for development, and developing the photoresist layer to remove selectively the first portion of the photoresist layer and the exposed portions of the second portion of the photoresist layer, as modified by the post-exposure bake. Remaining portions of the non-exposed regions of the photoresist layer form patterned structures of the semiconductor wafer and have a second height that is less than the first height of the photoresist layer.

Example 12. The method of Example 11, where: executing the post-exposure bake causes the first solubility-changing agent diffused into the first portion of the photoresist layer to cause the first portion of the photoresist layer to become soluble for development; and to modify the exposed regions of second portion of the photoresist layer to be soluble for development, the post-exposure bake causes a second solubility-changing agent activated by the actinic radiation in the exposed regions of the second portion of the photoresist layer to cause the exposed regions of the second portion of the photoresist layer to become soluble for development.

Example 13. The method of any one of Examples 11-12, where: the pre-exposure bake causes the first solubility-changing agent to diffuse from the agent-containing layer to the first portion of the photoresist layer up to a target depth, the target depth corresponding to a difference between the first height and the second height; and one or more of an agent type, an agent concentration, and an agent-containing layer thickness of the agent-containing layer are selected such that the pre-exposure bake causes the first solubility-changing agent to diffuse from the agent-containing layer to the first portion of the photoresist layer up to the target depth.

Example 14. The method of any one of Examples 11-13, where the first solubility-changing agent and the second solubility-changing agent include acid and the photoresist layer includes an acid-reactive material.

Example 15. The method of any one of Examples 11-14, where the agent-containing layer, as deposited, includes a polymer and the first solubility-changing agent or an agent-generating ingredient for generating the first solubility-changing agent.

Example 16. The method of any one of Examples 11 and 13-15, where: executing the pre-exposure bake causes the first solubility-changing agent to diffuse from the agent-containing layer to the first portion of the photoresist layer and causes the first solubility-changing agent diffused into the first portion of the photoresist layer to cause the first portion of the photoresist layer to become soluble for development; and to modify the exposed regions of second portion of the photoresist layer to be soluble for development, the post-exposure bake causes a second solubility-changing agent activated by the actinic radiation in the exposed regions of the second portion of the photoresist layer to cause the exposed regions of the second portion of the photoresist layer to become soluble for development.

Example 17. The method of any one of Examples 11-16, where, prior to the post-exposure bake, the exposed portions of the photoresist layer include the second solubility-changing agent, the second solubility-changing agent being generated in response to the actinic radiation.

Example 18. The method of any one of Examples 11-17, where depositing the agent-containing layer over the photoresist layer includes depositing an agent-containing material by spin-coating the agent-containing material over the photoresist layer.

Example 19. The method of any one of Examples 11-18, where the semiconductor wafer further includes a top coat formed over the photoresist layer prior to depositing the agent-containing layer over the photoresist layer, such that the top coat is between the photoresist layer and the agent-containing layer, the top coat configured to act as a diffusion barrier.

Example 20. The method of any one of Examples 11-19, where a lithography technology for exposing the photoresist layer to the pattern of actinic radiation includes one or more of immersion lithography technique or i-line lithography.

Example 21. The method of any one of Examples 11-20, further including using the patterned structures of the semiconductor wafer having the second height to form sub-resolution features in an underlying layer of the semiconductor wafer.

Example 22. The method of any one of Examples 11-21, where the first portion of the photoresist layer is relatively transparent to actinic radiation of the pattern of actinic radiation.

Example 23. A method includes forming first patterned structures on a semiconductor wafer, the first patterned structures defining first recesses and having a first height. Forming the first patterned structures includes depositing a photoresist layer on a semiconductor wafer to be patterned by photolithography, the photoresist layer having a second height that is greater than the first height; depositing a trimming layer over the photoresist layer; reducing, prior to developing the photoresist layer, the second height of the photoresist layer to the first height using a first solubility-changing agent diffused from the trimming layer into the photoresist layer; exposing the photoresist layer to a pattern of actinic radiation; and developing the photoresist layer, remaining portions of the photoresist layer forming microfabricated structures defining recesses. The method further includes depositing a first overcoat film on the semiconductor wafer, the first overcoat film filling the first recesses and covering the first patterned structures; diffusing a second solubility-changing agent of the first overcoat film into perimeter portions of the first patterned structures; and selectively removing the first overcoat film. The method further includes depositing a second overcoat film on the semiconductor wafer, the second overcoat film filling the first recesses and covering the first patterned structures, and executing a development process that removes a first portion of the second overcoat film to reveal the perimeter portions of the first patterned structures and removes the perimeter portions of the first patterned structures to define second patterned structures. The second patterned structures include remaining portions of the first patterned structures and second portions of the second overcoat film interspersed between the remaining portions of the first patterned structures, the second patterned structures defining second recesses.

Example 24. The method of Example 23, where the second recesses have a width of 10 nanometers or less.

Example 25. The method of any one of Examples 23-24, where the first solubility-changing agent and the second solubility-changing agent include acid.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method, comprising:
depositing a photoresist layer over a semiconductor wafer to be patterned by photolithography, the photoresist layer having a first height;
exposing the photoresist layer to a pattern of actinic radiation to form exposed regions and non-exposed regions of the photoresist layer;
depositing an agent-containing layer over the photoresist layer;
executing a post-exposure bake of the semiconductor wafer, the post-exposure bake modifying portions of the photoresist layer to form soluble portions of the photoresist layer for development, the soluble portions of the photoresist layer comprising the exposed regions of the photoresist layer and top portions of the non-exposed regions of the photoresist layer; and
developing the photoresist layer to remove selectively the soluble portions of the photoresist layer, remaining portions of the non-exposed regions of the photoresist layer forming patterned structures of the semiconductor wafer and having a second height that is less than the first height of the photoresist layer.

2. The method of claim 1, wherein to modify the portions of the photoresist layer to form the soluble portions of the photoresist layer for development, the post-exposure bake causes:
a first solubility-changing agent to diffuse from the agent-containing layer to the top portions of the non-exposed regions of the photoresist layer, the first solubility-changing agent causing the top portions of the non-exposed regions of the photoresist layer to become soluble for development; and
a second solubility-changing agent activated by the actinic radiation in the exposed regions of the photoresist layer to cause the exposed regions of the photoresist layer to become soluble for development.

3. The method of claim 2, wherein:
the post-exposure bake causes the first solubility-changing agent to diffuse from the agent-containing layer to the top portions of the non-exposed regions of the photoresist layer up to a target depth, the target depth corresponding to a difference between the first height and the second height; and
one or more of an agent type, an agent concentration, and an agent-containing layer thickness of the agent-containing layer are selected such that the post-exposure bake causes the first solubility-changing agent to diffuse from the agent-containing layer to the top portions of the non-exposed regions of the photoresist layer by the target depth.

4. The method of claim 2, wherein:
the first solubility-changing agent and the second solubility-changing agent comprise acid; and
the photoresist layer comprises an acid-reactive material.

5. The method of claim 4, wherein the agent-containing layer, as deposited, comprises:
a polymer; and
the first solubility-changing agent or an agent-generating ingredient for generating the first solubility-changing agent.

6. The method of claim 2, wherein prior to the post-exposure bake, the exposed portions of the photoresist layer comprise the second solubility-changing agent, the second solubility-changing agent being generated in response to the actinic radiation.

7. The method of claim 1, wherein depositing the agent-containing layer over the photoresist layer comprises depositing an agent-containing material by spin-coating the agent-containing material over the photoresist layer.

8. The method of claim 1, wherein a lithography technology for exposing the photoresist layer to the pattern of actinic radiation comprises one or more of:
immersion lithography technique; or
i-line lithography.

9. The method of claim 8, further comprising using the patterned structures of the semiconductor wafer having the second height to form sub-resolution features in an underlying layer of the semiconductor wafer.

10. A method, comprising:
depositing a photoresist layer on a semiconductor wafer to be patterned by photolithography, the photoresist layer having a first height;
depositing an agent-containing layer over the photoresist layer;
executing a pre-exposure bake of the semiconductor wafer, the pre-exposure bake causes a first solubility-changing agent to diffuse from the agent-containing layer to a first portion of the photoresist layer, the first portion of the photoresist layer being disposed between the agent-containing layer and a second portion of the photoresist layer;
selectively removing the agent-containing layer;
exposing, through the first portion of the photoresist layer, the second portion of the photoresist layer to a pattern of actinic radiation to form exposed regions and non-exposed regions in the second portion of the photoresist layer;
executing a post-exposure bake of the semiconductor wafer, the post exposure bake modifying the exposed regions of the second portion of the photoresist layer to be soluble for development; and
developing the photoresist layer to remove selectively the first portion of the photoresist layer and the exposed portions of the second portion of the photoresist layer, as modified by the post-exposure bake, remaining portions of the non-exposed regions of the photoresist layer forming patterned structures of the semiconductor wafer and having a second height that is less than the first height of the photoresist layer.

11. The method of claim 10, wherein:
executing the post-exposure bake causes the first solubility-changing agent diffused into the first portion of the photoresist layer to cause the first portion of the photoresist layer to become soluble for development; and
to modify the exposed regions of second portion of the photoresist layer to be soluble for development, the post-exposure bake causes a second solubility-changing agent activated by the actinic radiation in the exposed regions of the second portion of the photoresist layer to cause the exposed regions of the second portion of the photoresist layer to become soluble for development.

12. The method of claim 11, wherein:
the pre-exposure bake causes the first solubility-changing agent to diffuse from the agent-containing layer to the first portion of the photoresist layer up to a target depth, the target depth corresponding to a difference between the first height and the second height; and
one or more of an agent type, an agent concentration, and an agent-containing layer thickness of the agent-containing layer are selected such that the pre-exposure bake causes the first solubility-changing agent to diffuse from the agent-containing layer to the first portion of the photoresist layer up to the target depth.

13. The method of claim 11, wherein:
the first solubility-changing agent and the second solubility-changing agent comprise acid;
the photoresist layer comprises an acid-reactive material; and
the agent-containing layer, as deposited, comprises:
a polymer; and
the first solubility-changing agent or an agent-generating ingredient for generating the first solubility-changing agent.

14. The method of claim 10, wherein:
executing the pre-exposure bake causes the first solubility-changing agent to diffuse from the agent-containing layer to the first portion of the photoresist layer and causes the first solubility-changing agent diffused into the first portion of the photoresist layer to cause the first portion of the photoresist layer to become soluble for development; and
to modify the exposed regions of second portion of the photoresist layer to be soluble for development, the post-exposure bake causes a second solubility-changing agent activated by the actinic radiation in the exposed regions of the second portion of the photoresist layer to cause the exposed regions of the second portion of the photoresist layer to become soluble for development.

15. The method of claim 10, wherein a lithography technology for exposing the photoresist layer to the pattern of actinic radiation comprises one or more of:
immersion lithography technique; or
i-line lithography.

16. The method of claim 15, further comprising using the patterned structures of the semiconductor wafer having the second height to form sub-resolution features in an underlying layer of the semiconductor wafer.

17. The method of claim 10, wherein the first portion of the photoresist layer is relatively transparent to actinic radiation of the pattern of actinic radiation.

18. A method, comprising:
forming first patterned structures on a semiconductor wafer, the first patterned structures defining first recesses and having a first height, wherein forming the first patterned structures comprises:
depositing a photoresist layer on a semiconductor wafer to be patterned by photolithography, the photoresist layer having a second height that is greater than the first height;
depositing a trimming layer over the photoresist layer;
reducing, prior to developing the photoresist layer, the second height of the photoresist layer to the first height using a first solubility-changing agent diffused from the trimming layer into the photoresist layer;
exposing the photoresist layer to a pattern of actinic radiation; and
developing the photoresist layer, remaining portions of the photoresist layer forming microfabricated structures defining recesses;
depositing a first overcoat film on the semiconductor wafer, the first overcoat film filling the first recesses and covering the first patterned structures;
diffusing a second solubility-changing agent of the first overcoat film into perimeter portions of the first patterned structures;
selectively removing the first overcoat film;
depositing a second overcoat film on the semiconductor wafer, the second overcoat film filling the first recesses and covering the first patterned structures;
executing a development process that removes a first portion of the second overcoat film to reveal the perimeter portions of the first patterned structures and removes the perimeter portions of the first patterned structures to define second patterned structures, the second patterned structures comprising remaining portions of the first patterned structures and second portions of the second overcoat film interspersed between the remaining portions of the first patterned structures, the second patterned structures defining second recesses.

19. The method of claim 18, wherein the second recesses have a width of 10 nanometers or less.

20. The method of claim 18, wherein the first solubility-changing agent and the second solubility-changing agent comprise acid.
